(19) United States
(12) Patent Application Publication
(10) Pub. No.: US 2013/0312811 A1
(43) Pub. Date: Nov. 28, 2013

(54) NON-LATITUDE AND VERTICALLY MOUNTED SOLAR ENERGY CONCENTRATORS

(71) Applicant: Prism Solar Technologies Incorporated, (US)

(72) Inventors: Eric D. Aspnes, Tucson, AZ (US); Jose E. Castillo-Aguilella, Tucson, AZ (US); Ryan D. Courreges, Tucson, AZ (US); Paul S. Hauser, Tucson, AZ (US); Kevin R. Stewart, Niskayuna, NY (US)

(21) Appl. No.: 13/886,119

(22) Filed: May 2, 2013

Related U.S. Application Data
(60) Provisional application No. 61/641,722, filed on May 2, 2012.
(60) Provisional application No. 61/646,986, filed on May 15, 2012.
(60) Provisional application No. 61/656,820, filed on Jun. 7, 2012.

(51) Int. Cl. H01L 31/052; G06F 17/50

(52) U.S. Cl. CPC H01L 31/0525; G06F 17/5009
USPC 136/246; 136/259; 703/13

(57) ABSTRACT

A solar-energy concentrator optimized for operating in a substantially vertical orientation and method for collecting sunlight with such concentrator. The concentrator includes a photovoltaic (PV) module having a PV cell and layers containing diffraction gratings that may be spatially stacked or multiplexed. Diffraction gratings define corresponding diffraction patterns optimized for solar energy harvesting depending on which direction the concentrator is facing. Additionally, a method of designing a hologram for concentrating solar energy onto an adjacent photovoltaic chip is provided. The method includes selecting a photovoltaic chip material, selecting a photovoltaic cell geometry, selecting a first construction angle, selecting an installation latitude, selecting an installation tilt angle, and modeling hologram performance as a function of a second construction angle and a design wavelength.

### CROSS-REFERENCE TO RELATED APPLICATIONS

The present application claims benefit of and priority from the U.S. Provisional Applications Nos. 61/641,722 filed on May 2, 2012 and titled “Non-Latitude Mounted, Holographic Photovoltaic Configurations”; 61/646,986 filed on May 15, 2012 and titled “Vertically Mounted Solar Energy Concentrator”; and 61/656,820 filed on Jun. 7, 2012 and titled “Vertically Mounted Solar Energy Concentrator”. The disclosure of each of the above-mentioned patent applications is incorporated herein by reference in its entirety.

### TECHNICAL FIELD

The present invention relates to system and method for fabrication of a holographic PV-module-based solar-power concentrator and, more particularly, to systems and methods employing diffraction gratings, spatially multiplexed as layers of the solar power concentrator, to increase the amount of solar energy incident onto the PV cell, for both vertically mounted and other non-latitude mounting conditions.

### BACKGROUND

Solar energy will satisfy an important part of future energy needs. While the need in solar energy output has grown dramatically in recent years, the total output from all solar installations worldwide still remains around 7 GW, which is only a tiny fraction of the world's energy requirement. High material and manufacturing costs, low solar module efficiency, and shortage of refined silicon limit the scale of solar power development required to effectively compete with the use of coal and liquid fossil fuels.

The key issue currently faced by the solar industry is how to reduce system cost per unit of efficiency of energy conversion. The main-stream technologies that are being explored to improve the cost-per-kilowatt of solar power are directed to (i) improving the efficiency of a solar cell that comprises solar modules, and (ii) delivering greater amounts of solar radiation onto the solar cell. In particular, these technologies include developing thin-film, polymer, and dye-sensitized photovoltaic (PV) cells to replace expensive semiconductor material based solar cells, the use high-efficiency smaller-area photovoltaic devices, and implementation of low-cost collectors and concentrators of solar energy.

While the reduction of use of semiconductor-based solar cells is showing great promise, for example, in central power station applications, it remains disadvantageous for residential applications due to the form factor and significantly higher initial costs. Indeed, today's residential solar arrays are typically fabricated with silicon photovoltaic cells, and the silicon material constitutes the major cost of the module. Therefore techniques that can reduce the amount of silicon used in the module without reducing output power will lower the cost of the modules.

The use of devices adapted to concentrate solar radiation on a solar cell is one of such techniques. Various light concentrators have been disclosed in related art, for example a compound parabolic concentrator (CPC); a planar concentrator such as, for example, a holographic planar concentrator (HPC) including a planar highly transparent plate and a holographically-recorded optical element mounted on its surface; and a spectrum-splitting concentrator (SSC) that includes multiple, single junction PV cells that are separately optimized for high efficiency operation in respectively-corresponding distinct spectral bands. A conventionally-used HPC is known to be limited in that the collection angle, within which the incident solar light is diffracted to illuminate the solar cell, is limited to about 45 degrees. Production of a typical SSC, on the other hand, requires the use of complex fabrication techniques.

In most of the existing systems used for concentration of solar radiation that employ holographic diffractive gratings, the manner in which the gratings are disposed in relation to a given PV cell is of substantial importance, as it influences the efficiency of sun-light collection and redirection of the collected light towards the PV cell.

Correctly mounting and orienting solar cells is also key to improving efficiency. Conventionally, solar panels are mounted and oriented such that the surface of the panel is orthogonal to the direction of incoming light from the sun for most of the time. In other words, the optimum orientation of a conventional solar panel is with its surface normal pointing toward the sun. This orientation allows for maximum transfer efficiency because it maximizes the projected area of the solar panel when viewed from the direction of the sun. The sun, however, traverses the sky during the course of the day, and reaches a different zenith (i.e., maximum noontime height above the horizon) each day depending on the day of the year. Ideally, to maximize transfer efficiency, a solar panel will be mounted on a moving heliostatic or equatorial mounting system that dynamically rotates the panel (about an azimuthal axis) during the course of the day such that the panel tracks the sun, and also adjusts the tilt angle (the angle made between the plane of the panel and a planar approximation of the surface of the earth at the panel location) to compensate for the height of the sun above the horizon with the changing seasons. Heliosatic mounts, however, are cumbersome, expensive, prone to failure, and commercially impractical for many installations. For a static mounting situation, conventional panels are mounted such that they are south facing (i.e., such that the ground projection of the surface normal to the active face of the panel points south), and with a tilt angle that is equal to the latitude where the panel is installed. For example, for a static mounted conventional panel located in Tucson, Ariz., which is situated at approximately 32 degrees north latitude, a panel would be conventionally mounted with a 32 degree tilt angle and oriented in a south facing direction.

### SUMMARY OF THE INVENTION

Applicants have discovered synergies between the use of holographic planar concentrators and off-latitude mounting conditions. In other words, Applicants have discovered that much higher than previously obtained levels of solar concentration can be generated by optimizing holographic planar concentrator designs and mounting solar panels at non-latitude angles. Embodiments of the invention include a design methodology, based on simulation and experimental results, which shows that the traditional use of holograms in solar applications mounted at latitude can be improved upon. Embodiments of the invention include both a design methodology that shows that many other holographic mounting conditions provide much improved holographic performance, when those holograms are compared to holograms mounted at latitude conditions, and HPC designs based on Applicant's methodology. By employing embodiments of the invention it can be shown that south facing, near horizontal and vertical mounting conditions have higher than expected levels of solar concentration when HPCs are optimized for use at those mounting angles. In certain embodiments, HPC designs are provided to optimize the performance of conventional latitude mounts. In certain embodiments, this is accomplished by using dissimilar holograms above and below the PV material (i.e., chip) in the same plane.

In particular, applicants have discovered optimal HPC designs for use in vertically mounted applications. Such designs, disclosed herein, are particularly useful for mounting on the exterior walls of tall buildings, Vertically mounted HPC based PV cells according to embodiments of the invention may be retrofitted to existing buildings, and therefore do not require that buildings be designed with special (e.g., latitude inclined) mounting surfaces to receive PV cells.

In one embodiment, the invention includes a solar energy concentrator having a front configured to be exposed to sunlight. The concentrator includes a photovoltaic (PV) module layer, which includes a PV cell that defines a PV plane corresponding to the front, and a first diffraction grating disposed in a first plane that is substantially parallel to the PV plane. The first diffraction grating has a first diffraction pattern defining a first direction. The concentrator also has a second diffraction disposed in a second plane that is substantially parallel to the PV plane. The second diffraction grating has a second diffraction pattern defining a second direction, the first and second directions forming an angle. The concentrator is configured to have light diffracted by at least one of the first and second diffraction gratings to be totally internally reflected towards the PV cell at a surface of the concentrator.

In another embodiment, the first diffraction grating is configured such that sunlight that has interacted with the second diffraction grating interacts with the first diffraction grating. In yet another embodiment, the PV cell includes a plurality of PV cells, the first diffraction grating includes a first array of gratings having substantially equal spatial orientation and the second diffraction gratings includes a second array of gratings having substantially equal spatial orientation. The first and second arrays define areas bounded by gratings from the arrays, and PV cells from said plurality of PV cells disposed in said areas.

In another embodiment, the first and second diffraction gratings are holographic diffraction gratings. In yet another embodiment, the first and second diffraction gratings have substantially co-extensive normal projections on the plane defined by the PV cell. In another embodiment, the first and second diffraction gratings are adjoining one another.

In another embodiment, the solar concentrator includes an optical layer encapsulating at least one of said PV cell and first and second diffraction gratings. In another embodiment, the PV cell of the concentrator includes a monofacial PV cell.

In yet another embodiment, the concentrator includes and second optically-transparent substrates sandwiching the photovoltaic module layer, the first diffraction grating, and the second diffraction grating therebetween to define an optical stack. The second substrate corresponds to the front, and the optical stack is configured to ensure that light that has interacted with the second diffraction grating is totally internally reflected by a surface of the optical stack towards the PV cell. The light that has interacted with the first diffraction grating is totally internally reflected by a surface of the optical stack towards the PV cell. In a further embodiment, the PV cell includes a bifacial PV cell and the optical stack is configured to have the light, which has interacted with the first diffraction grating, to be received by a face of the PV cell that is opposite to the front. In another embodiment, at least one of the first and second diffraction gratings has a parameter that varies as a function of a distance between a point at which such parameter is defined and the PV cell.

Other embodiments include a method of designing a hologram for concentrating solar energy onto a photovoltaic chip. The hologram is characterized by a first construction angle, a second construction angle and a design wavelength. The method involves selecting a photovoltaic chip material, selecting a photovoltaic cell geometry, selecting a first construction angle, selecting an installation latitude, selecting an installation tilt angle, modeling hologram performance as a function of a second construction angle and a design wavelength, and selecting a combination of second construction angle and design wavelength that yields the optimum performance for a given tilt angle and latitude.

In other embodiments of the method, the step of modeling hologram performance as a function of a second construction angle and a design wavelength includes using approximate couple wave analysis to determine the amount of light concentrated by a hologram onto an adjacent photovoltaic chip throughout the year. In further embodiments, the first construction angle is selected to be above the critical angle for a panel material in which the hologram is to be embedded.

In certain embodiments, the invention includes a photovoltaic panel. The panel includes a photovoltaic chip embedded in a transparent material, the transparent material having a first surface and a second surface, the surfaces being mutually parallel. The photovoltaic chip has a spectral response such that the photovoltaic chip is capable of converting incident light within a predetermined wavelength range into electrical current. The panel also includes a primary hologram located above and adjacent to the photovoltaic chip and embedded in the transparent material such that it is substantially coplanar with said photovoltaic chip, the primary hologram being characterized by a first construction angle, a second construction angle and a design wavelength. The primary hologram and the photovoltaic chip are substantially parallel to the first and second surfaces. The primary hologram acts as a diffraction grating, diffracting light within said predetermined wavelength range that is incident on the first surface of the transparent material at a first angle laterally at a second angle in a downward direction toward the photovoltaic chip. The second angle is such that light diffracted by the primary hologram undergoes total internal reflection upon intersection with the second surface.

In another embodiment, the photovoltaic panel has a tilt angle that is substantially equal to the latitude of the location of the panel's installation, wherein tilt angle is the angle made between the plane of the photovoltaic chip and the local horizontal. In other embodiments, the tilt angle is not equal to the latitude of the location of the panel's installation, wherein tilt angle is the angle made between the plane of the photovoltaic chip and the local horizontal. In still other embodiments, the tilt angle is substantially 90 degrees.

In certain embodiments of the panel, the primary hologram can be characterized according to a first construction angle, a second construction angle, and a design wavelength, and the first construction angle is chosen to be above the critical angle of the transparent material. The second construction angle and design wavelength are chosen to yield a concentration of greater than 0.25.

In some embodiments, the panel includes a conjugate hologram located below and adjacent to the photovoltaic chip and embedded in the transparent material such that it is substantially coplanar with said photovoltaic chip, the conjugate hologram being characterized by a first construction angle, a second construction angle and a design wavelength. The conjugate hologram and the photovoltaic chip are substantially parallel to the first and second surfaces. The conjugate hologram acts as a diffraction grating diffracting light within said predetermined wavelength range that is incident on the first surface of the transparent material at a first angle laterally at a third angle in an upward direction toward the photovoltaic chip. The third angle is such that light diffracted by the conjugate hologram undergoes total internal reflection upon intersection with the second surface.

Embodiments of the invention have certain advantages. According to embodiments of the invention, HPCs are shown to work at many latitudes, mounting angles and with a variety of the most common photovoltaic (PV) materials, in contrast to conventional latitude mounting arrangements. Embodiments of the invention allow for optimization of concentrating holograms for the latitude at which they are located, the mounting angle of the PV structure, and the PV material used, to extract the maximum possible benefit. Certain embodiments allow for a determination of the ideal hologram design and mounting angle for all photovoltaic materials.

### BRIEF DESCRIPTION OF THE DRAWINGS

The invention will be more fully understood by referring to the following Detailed Description in conjunction with the Drawings, of which:

FIG. 1A is a schematic of a holographic planar concentrator.

FIG. 1B is a schematic of an alternative holographic planar concentrator.

FIG. 2 is a top view schematic of a planar solar energy concentrator including multiple groups of PV cells.

FIG. 3 is a diagram illustrating the use of an encapsulating layer.

FIG. 4A is a diagram illustrating apparent path of the sun in the sky.

FIG. 4B is a schematic plot of efficiency with which a diffraction grating disposed in a vertical plane diffracts sunlight depending on the time of the day, season, and/or angle of incidence.

FIGS. 4C, 4D, 4E are plots of several characteristics of the diffraction grating that is mounted in a vertical plane to face the south and diffract incident sunlight.

FIGS. 5A, 5B, 5C, 5D are diagrams illustrating an embodiment of the invention.

FIGS. 6A, 6B are diagrams illustrating a related embodiment of the invention.

FIGS. 7A, 7B are diagrams illustrating another embodiment of the invention.

FIGS. 8A, 8B, 8C are plots depicting dispersion characteristics of a grating of the embodiment of FIGS. 7A, 7B.

FIG. 9 is a diagram illustrating a related embodiment of the invention.

FIG. 10 is a diagram illustrating an alternative embodiment of the invention.

FIGS. 11, 12, 13A, 13B, 13C, and 14 depict portions of alternative embodiments.

FIG. 15 is a diagram of grating parameters defined for a blazed grating.

FIG. 16 is a plot illustrating spectral dependencies of diffraction efficiencies of three types of diffraction gratings for use with an embodiment of the invention.

FIG. 17 is a schematic diagram showing a tilted solar panel using HPCs according to an embodiment of the invention.

FIG. 18 is a schematic diagram of an HPC solar panel having a primary and conjugate hologram for optimization at an arbitrary tilt angle according to an embodiment of the invention.

FIG. 19 is a chart showing the spectral response curves for common PV materials.

FIG. 20A is a chart showing the solar concentration created by a primary hologram as a function of construction angle and design wavelength for a latitude mounted solar panel.

FIG. 20B is a chart showing the solar concentration created by a conjugate hologram as a function of construction angle and design wavelength for a latitude mounted solar panel.

FIG. 21A is a chart showing the solar concentration created by a primary hologram for a vertical mounting condition as a function of construction angle and design wavelength.

FIG. 21B is a chart showing the solar concentration created by a conjugate hologram for a 5 degree mounting condition as a function of construction angle and design wavelength.

FIG. 21C is the chart of FIG. 6a for a vertically mounted primary hologram flattened to show an advantageous range of design conditions for achieving high concentration.

FIG. 21D is the chart of FIG. 6B for a near-horizontally mounted conjugate hologram flattened to show an advantageous range of design conditions for achieving high concentration.

FIG. 22 is a collection of graphs showing the solar concentrations achievable by optimized primary and secondary HPCs for different latitudes as a function of mounting angle for single crystal silicon PV chips.

FIG. 23 is a collection of graphs showing the solar concentrations achievable by optimized primary and secondary HPCs for different latitudes as a function of mounting angle for poly silicon PV chips.

FIG. 24 is a collection of graphs showing the solar concentrations achievable by optimized primary and secondary HPCs for different latitudes as a function of mounting angle for CIGS PV chips.

FIG. 25 is a collection of graphs showing the solar concentrations achievable by optimized primary and secondary HPCs for different latitudes as a function of mounting angle for CdTe PV chips.

FIG. 26 is a flow chart summarizing the steps of optimizing holographic planar concentrators for a given tilt angle and installation latitude according to an embodiment of the invention.

### DETAILED DESCRIPTION

As broadly used and described herein, the reference to a layer as being “carried” on or by a surface of an element refers to both a layer that is disposed directly on the surface of that element or disposed on another coating, layer or layers that are, in turn disposed directly on the surface of the element.

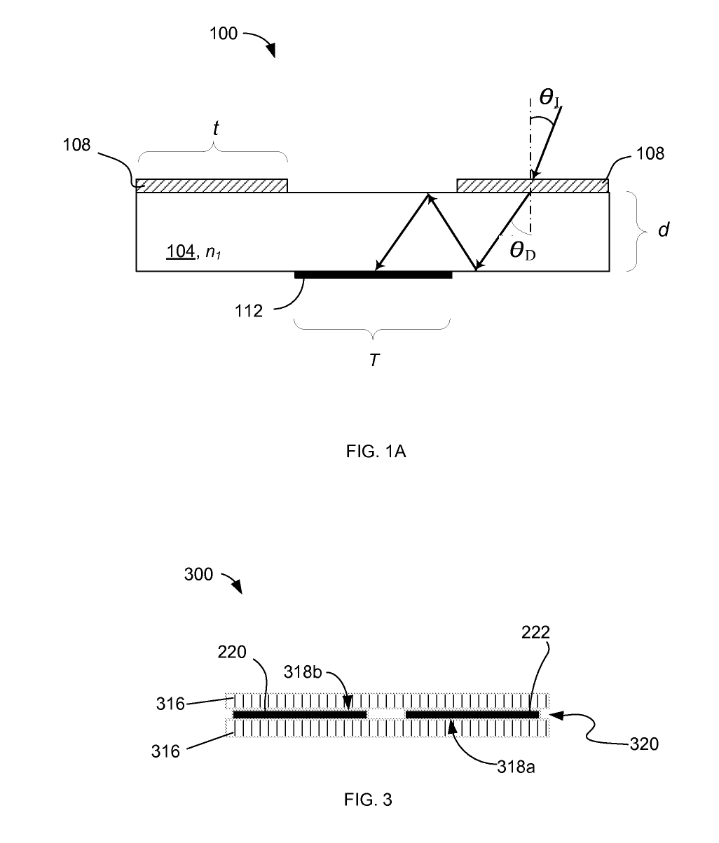

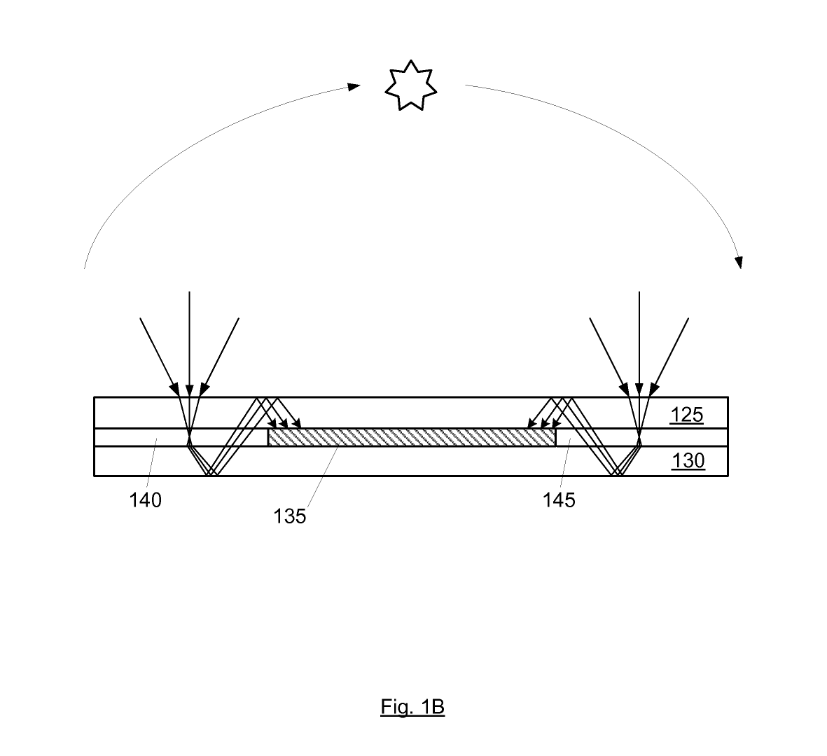

While there exists a variety of sun-light concentrators, one example of typical devices currently used for concentration of solar radiation for the purposes of PV-conversion is shown schematically in FIG. 1A. An HPC-photovoltaic module 100 of FIG. 1B, shown in a cross-sectional view, typically includes a highly-transparent planar substrate 104 of thickness d (such as, for example, substrate made of glass or appropriate polymeric material having the refractive index n₁) at least one diffractive structure 108, having width t, at a surface of the substrate 104. Such diffractive structure may include, for example, a holographic optical film (such as gelatin-on-PET film stack) in which a plurality of multiplexed diffraction gratings have been recorded with the use of laser light. The diffractive structure 108 can be optionally capped with a protective cover layer (not shown). The substrate 104 is typically cooperated with a solar-energy-collecting device 112 such as a PV cell. The diffractive structures 108 diffract wavelengths usable by the PV cell 112, while allowing the light at unusable wavelength to pass through, substantially unabsorbed. The usable energy is guided via the total internal reflection at the glass/air or glass/cover interface to strings of solar cells, resulting in up to a 3× concentration of solar energy per unit area of PV material as compared to a PV module that is devoid of such holographically-defined diffractive element.

Further in reference to FIG. 1A, the PV cell 112 of width T is juxtaposed with the second surface of the substrate 104 in opposition to the diffractive structures 108 and in such orientation that ambient (sun-) light I, incident onto the structure 108 at an angle θ_{I}, is diffracted at an angle θ_{D} onto the cell 112 either directly or upon multiple reflections within the substrate 104.

FIG. 1B is a schematic diagram of an alternative transmission hologram HPC-based photovoltaic module 120. The module 120 includes a first and second substrate layers 125, 130, between which is disposed a PV chip or cell 135. Roughly co-planar with and adjacent to and on either side of cell 135 are disposed transmission holograms 140, 145. Transmission holograms take incoming light incident on the module of FIG. 1B at roughly normal incidence and diffract such light in the direction of chip 135, with each hologram 140, 145 being biased to preferentially diffract light into the diffractional order that is biased toward PV cell 135. After diffraction, light is guided to PV chip 135 by total internal reflection in substrate layers 125, 130. The configuration of FIG. 1B (like the configuration in FIG. 1A) is not in any way limiting. Other HPC-based solar modules use reflection rather than transmission holograms, and can use holograms in planes other than the plane of PV chip 135. While the HPC-based module of FIG. 1B is shown using a monofacial chip, where light is guided to be incident on a front surface, use of bi-facial cells is acceptable also. In the arrangement of FIG. 1B, holograms 140, 145 are identical in configuration (i.e., in grating spacing), except that they are biased in opposite directions, i.e., where one hologram is designed to preferentially diffract light into a 1st diffractional order, the other hologram is designed to preferentially diffract light into a −1st diffractional order. The design output construction angle for the holograms is equal, but opposite, as between them.

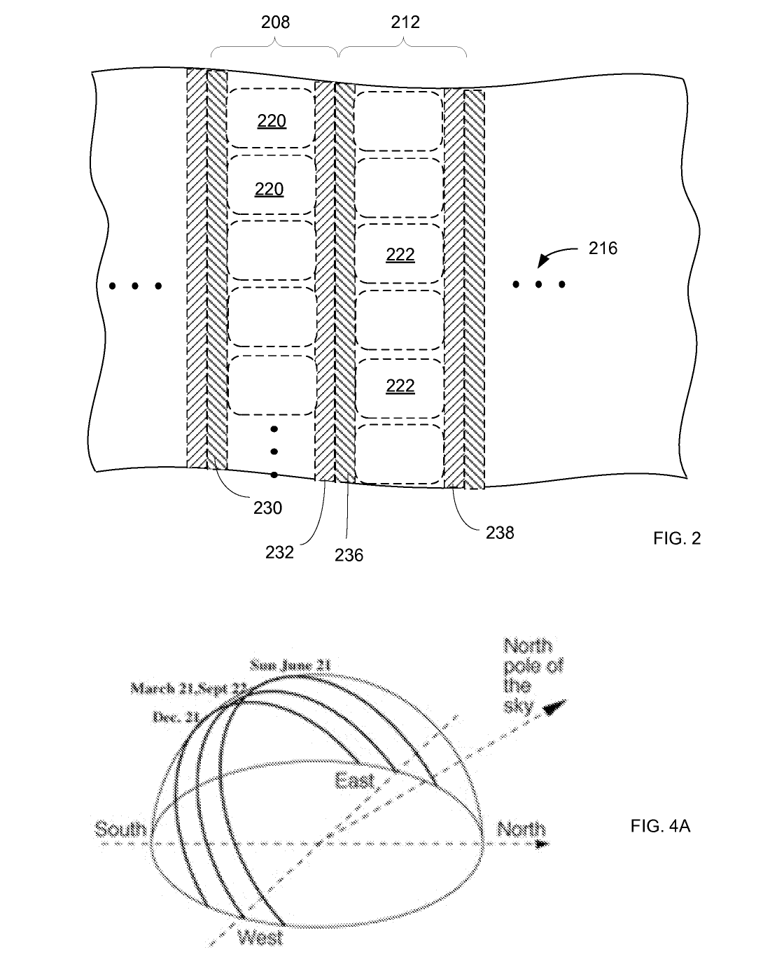

In practice, a PV module typically includes multiple PV cells and multiple diffractive elements in optical communications with such cells. To this end, a top view of a PV module containing an array of PV cells (whether monofacial or bifacial) is schematically shown in FIG. 2. The embodiment of FIG. 2 is a multi-portion (or multi-period) embodiment and, as shown, includes two portions 208, 212. Additional portions or periods are not shown but indicated with three-point designators 216. Each of the portions or periods 208, 212 includes a corresponding PV-cell (220 or 222) that is surrounded by (and optionally co-planar with) respectively-corresponding diffractive element layers (230, 232) or (236, 238) containing diffraction gratings (that are, optionally, holographically defined). The layers 230, 232, 236, 238 may operate in transmission, reflection, or both transmission and reflection depending on the embodiment. Various implementations describing spatial coordination of the PV cells and corresponding diffraction gratings are presented in other commonly assigned patent applications.

It is appreciated that in addition to the PV module layer and the diffractive element layer, an embodiment of the HPC of the invention may include an encapsulating layer. Because PV-cells are thin and delicate, and thereby subject to breakage or other damage, for example by scratching, chemical etching, or the like, PV-cells are optionally encapsulated with an optically and IR clear adhesive such as ethyl vinyl acetate (“EVA”) or silicone. In certain embodiments, such as that shown in FIG. 3, for instance, an encapsulant 316 is provided in the form of two sheets of EVA that are laminated to sides 318a, 318b of the PV-module layer 320 (for example, before the resulting assembly is laminated to glass, not shown, although the exact sequence of steps in the lamination process can vary). In the case of a monofacial cell, instead of one glass layer, a backsheet or protective sheet made of some polymeric material (e.g., polyethylene terepthalate (“PET”)) is optionally provided to which the PV chips are first adhered before being laminated to front side glass with an encapsulant layer. In some conventional embodiments, a backsheet is provided with encapsulant pre-deposited. In some conventional embodiments, glass is used as a backsheet, even for monofacial cells. In a related embodiment, a single encapsulant layer may be used in juxtaposition with one side of the PV-module.

The spectral dependence of operational performance of a diffraction grating becomes more pronounced as the angle of deviation of light diffracted by the grating from the direction of propagation of light incident onto the grating is increased. When light incident on a diffraction grating has a very broad spectrum (which is the case for sunlight incident onto a diffractive element of a solar energy concentrator), portions of incident light at wavelengths outside of the operational bandwidth of the diffraction grating are not diffracted by the grating and are substantially transmitted by it (assuming insignificant absorbance of the material of the grating and not taking into account the residual specular reflection and scattering of light).

However, the diffraction efficiency of a diffraction grating is dependent not only on the spectral composition of the incident light but also on the angle at which the incident light impinges on the grating. As a result, the efficiency of concentration of solar energy by a planar PV-module that is not equipped with a sun-tracking gear (for example, an HPC discussed above) employing diffraction gratings is sensitive to the angles of incidence of sunlight. This sensitivity is heightened in the case when such “non-tracking” HPC is mounted vertically. Fixed vertical or substantially vertical mounting of a solar-energy concentrator device can be employed on the walls of the buildings to collect solar energy impinging upon the walls. Alternatively or in addition, a non-tracking HPC can be installed in a window-frame of a building to serve a dual-purpose: to convert incident sun-light into electrical energy and let a portion of the sun-light through to brighten the interior of the building (to act as a window-version of a sky-light, so to speak). Examples of such substantially-vertical installations of a non-tracking HPC include roadway walls and awning structures of a building and building facades. It should be recognized that in such “building-integrated” photovoltaic module market product characteristics besides those reflecting energy-harvesting abilities and cost-per-watt are of importance. These additional characteristics of PV modules that are, by virtue of their vertical installation, prominent, ever-noticeable and obtrusive include cosmetic appeal and light-guiding abilities.

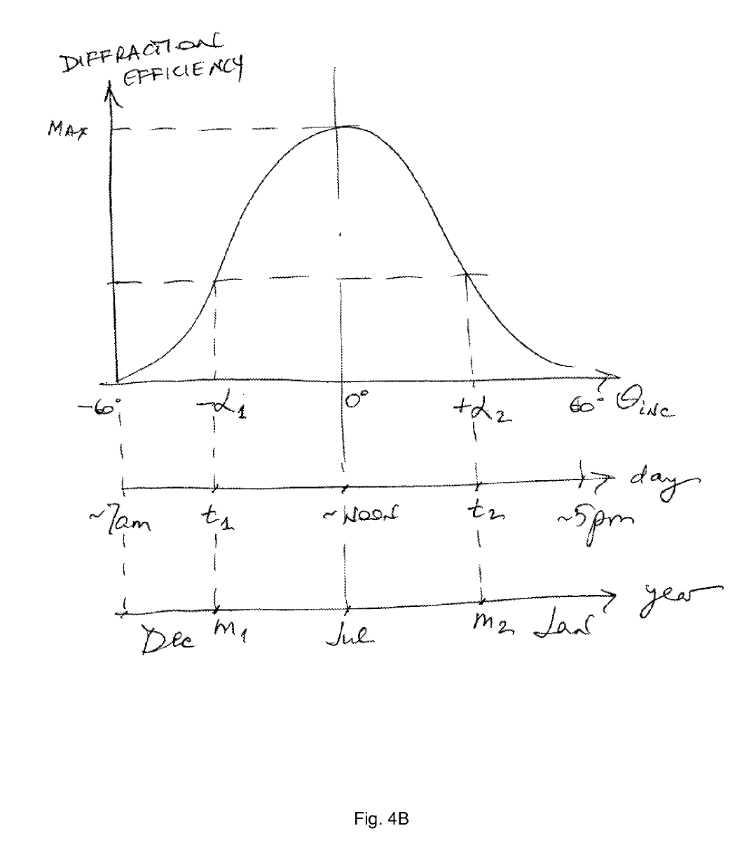

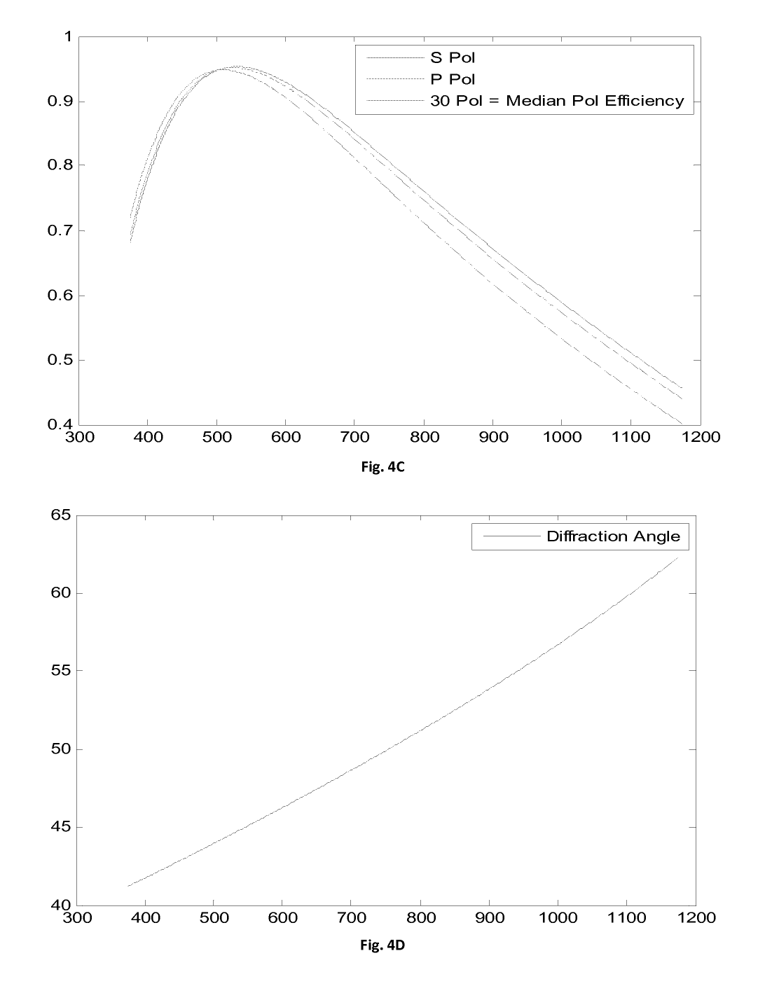

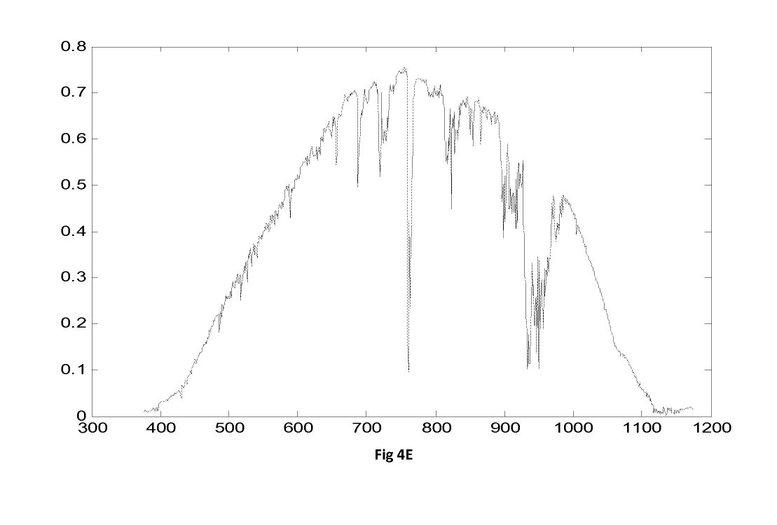

Analysis of a vertically-positioned diffraction grating reveals that efficiency of diffraction of incident sunlight by such grating changes in a course of a day and throughout the seasons, due to the fact that a position of the sun in the sky (both the azimuth and the altitude) are changing in a course of the day and throughout the seasons. In addition, the operation of such a grating depends on orientation of its diffraction pattern (or “diffraction grooves”, defined by spatial distribution of index of refraction of the medium of the corresponding grating). This is better understood in reference to FIG. 4A, which provides a schematic of apparent path of the sun in the sky, as observed in northern hemisphere. A plot of FIG. 4B, offering an illustration of an approximate dependence of diffraction efficiency of a grating facing the south on a time of the day and a month of the year, takes the information of FIG. 4A into account. It is observed that operation of the diffraction grating within the useful “bandwidth” of diffraction efficiency (defined between its maximum and a chosen minimum values) can be achieved only within the limited range of angles of incidence θ_{inc} (between about α₁ and about α₂) which is satisfied only within a limited time-window during the day (between about t₁ and about t₂) and limited number of months during the year (between about m₁ and m₂). It is also appreciated that such efficiency depends on a direction in which the gratings is facing (north-south, east-west, or in between). Accordingly, embodiments of a non-tracking HPC module of the invention, employing a grating configured to redirect apportion of sun-light incident onto the grating towards the PV-cell of the module are adapted to optimize the module-orientation-dependent solar-energy collection efficiency.

Embodiments of the invention utilize any appropriate type of a diffraction grating (a holographically-defined grating such as a phase grating operating in reflection and/or the one operating in transmission, and/or a conventional blazed reflective grating, for example) and either a mono-facial or a bi-facial PV cell. A portion of light diffracted by a grating in an embodiment of the invention is redirected towards a PV-cell through a total internal reflection (TIR) at a dielectric boundary of a PV module of the invention. Generally, HPCs and PV modules such as those discussed in commonly-assigned provisional patent applications Nos. 61/641,143, 61/569,097 (non-provisional application Ser. Nos. 13/708,160 and 13/874,633), for example, can be employed with embodiments of the invention. The disclosure of each of the above-mentioned applications is incorporated herein by reference it its entirety. It is appreciated that the grating(s) of the PV module are adapted for optimized diffraction operation for the day-time period from about a sunrise to about a sunset and for a range of zenith angles of about −23.45 degrees to about +23.45 degrees (as measure with respect to a vertical), which approximately corresponds to the latitude of the PV-module installation. FIGS. 4C, 4D, and 4E illustrate typical characteristics of a holographic grating employed with a south-facing embodiment of the invention. FIG. 4C illustrated diffraction efficiency as a function of wavelength of light and its polarization state; FIG. 4D shows the angular dispersion of the gratings as a function of wavelength of light (note that the practically usable range is about 20 to 30 degrees); and a plot of FIG. 4E shows a product of the diffraction efficiency of FIG. 4D with the spectrum of the atmospheric transmission and the response curve of the silicon (to take into account the spectral response of the PV cell), boasting the peak of about 75% and a bandwidth of about 500 nm.

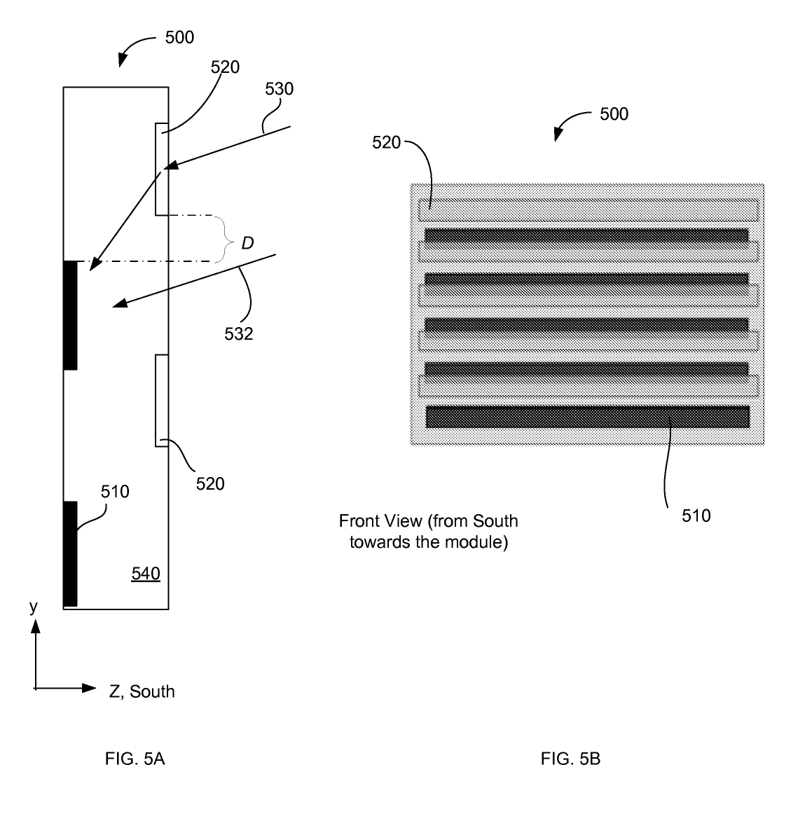

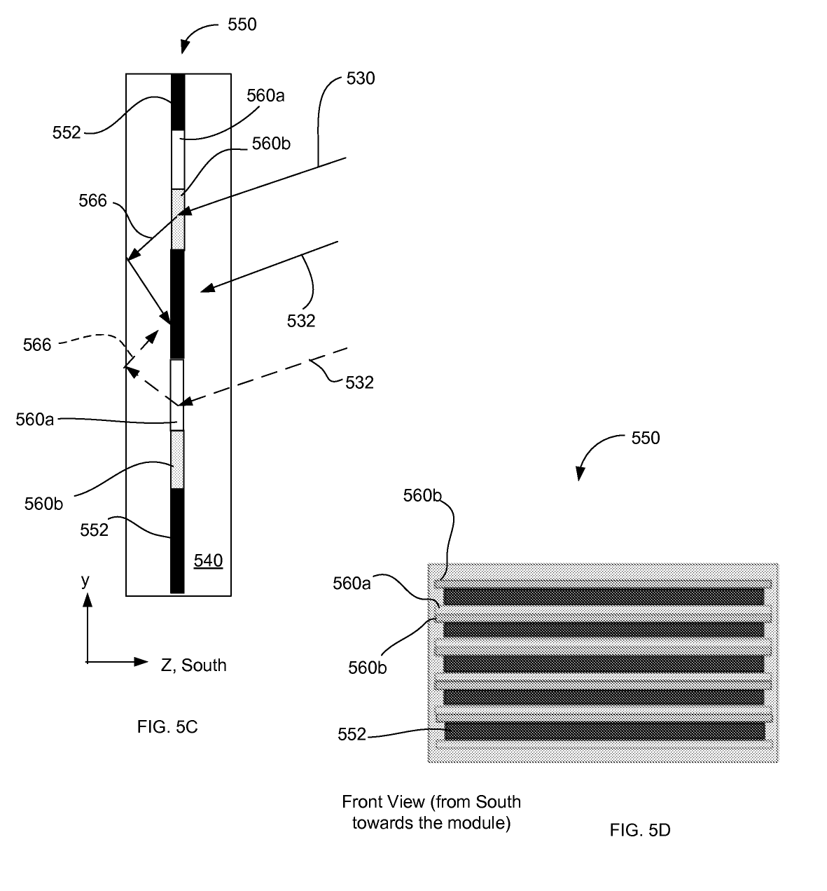

For simplicity of illustrations, the following discussion refers to PV modules of the invention that are substantially vertically mounted in the northern hemisphere. PV modules mounted to face the equator receive very little light—if at all—from the backside. Accordingly, the PV cell does not have to be a bifacial PV cell. An example of a PV-module 500 of the invention employing monofacial PV cell(s) 510 and an array of diffractive gratings 520. A diffraction grating pattern of each of the gratings in the array 520 (which, in the case of imprinted grating such as a blazed grating corresponds to the grating grooves or rulings, and in the case of a holographically-defined gratings corresponds to the iso-lines of refractive index distribution in a plane parallel to the plane of the grating) generally corresponds to the extent of a grating in the array, i.e. is substantially horizontal in the local system of coordinates, as shown in diagrams of FIGS. 5A, 5B. A beam of sunlight 530 incident onto a grating 520 is diffracted, in transmission, towards the PV cell 510. A beam 532 that impinges on a surface of the module devoid of the grating passes through the encapsulation and/or structural layer 540 directly towards the cell 510. The gratings 520 are transversely (in a plane of the module 500) offset with respect to the PV cells 510 adapted to optimize the amount of radiant flux directed to the PV cells 510. FIGS. 5C, 5D provide an example of a south-facing embodiment 550 employing bi-facial PV cells 552 in which diffraction gratings 560a, 560b (that are substantially co-planar with the cells 552 and have different operational parameters) are both adapted to work in transmission. The module 550 is configured to ensure that light 566 diffracted by either of the gratings 560a, 560b is TIR'd at the back surface 570 of the module. In a related embodiment, spatially multiplexed gratings (such as those discussed in U.S. Provisional Application No. 61/641,143, non-provisional application Ser. No. 13/874,633) are optionally employed.

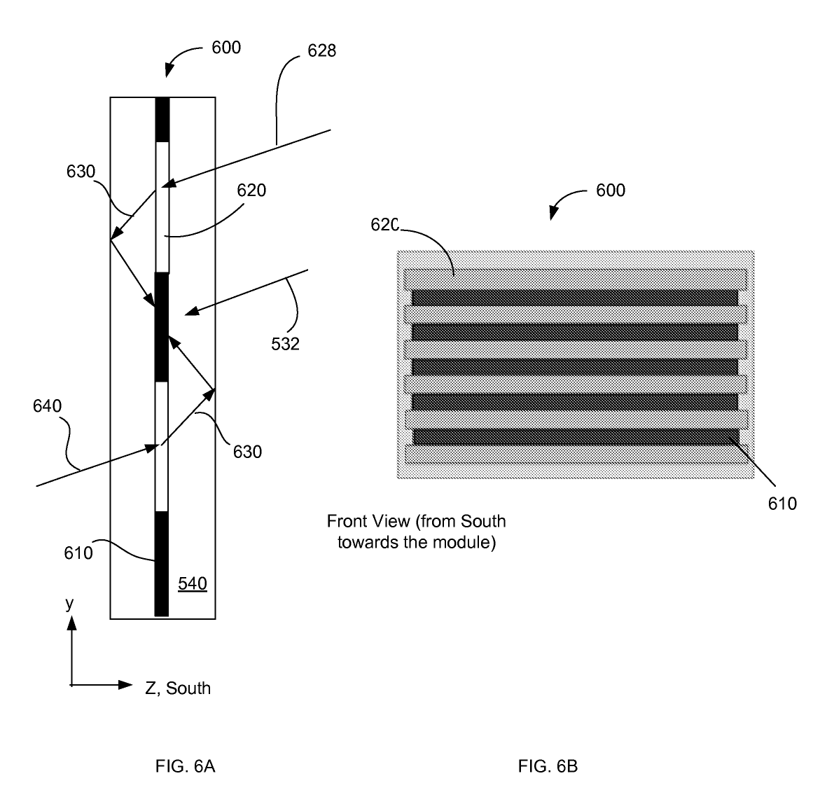

FIGS. 6A, 6B illustrate the use of PV module 600 that is substantially vertically disposed to face the equator and that employs bifacial PV cells 610 to collect residual light incident upon the module from the northern side. The diffractive element layer containing diffraction gratings 620 is substantially co-planar with the POV cells 610. Light 630 diffracted by the gratings 620 (from light 628) is redirected towards the PV cells 610 with the use of TIR at surfaces 600a, 600b of the module 600. Light 640 indicates light incident onto the module from the northern side, such as scattered/reflected light and/or direct sunlight during portions of a summer solstice day.

It is appreciated that both embodiments 500, 600 (of FIGS. 5A, 5b, 6A, 6B) that employ diffraction gratings 520, 620 having horizontally oriented (in local system of coordinates) diffraction pattern perform stably during the day but varies from season to season. According to embodiments of the invention, in comparison, and in further reference to the diagram of FIG. 4A, a vertically-positioned embodiment of an HPC of the invention the gratings of which possess vertically-oriented diffraction pattern performs stably across the seasons, but within limited time-window each day.

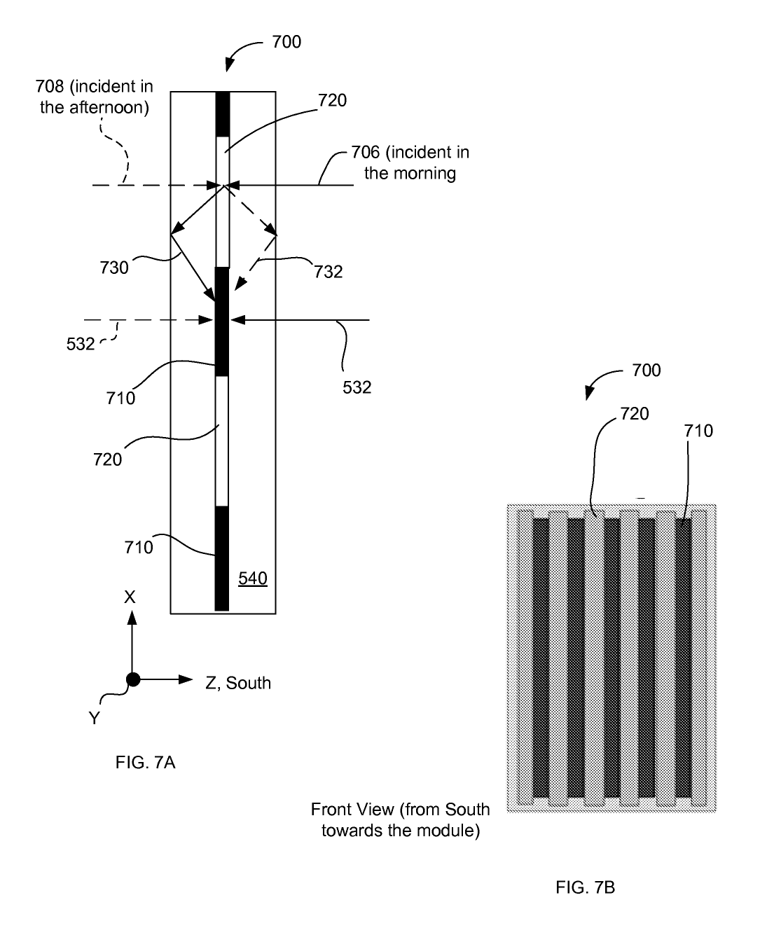

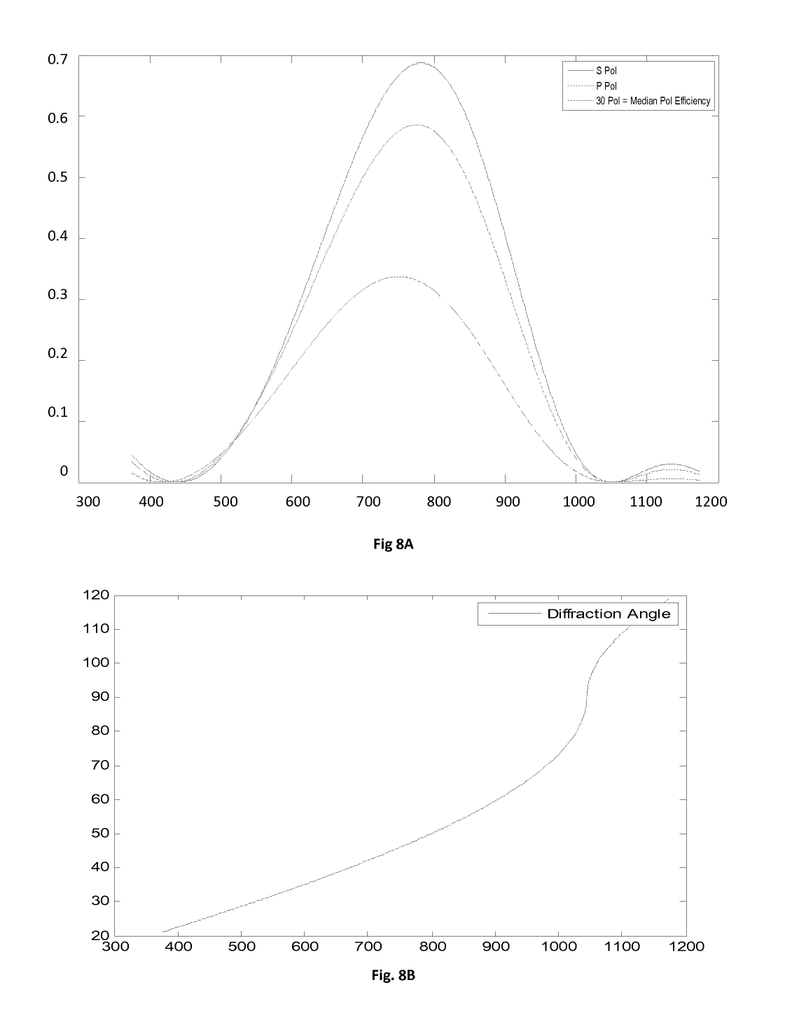

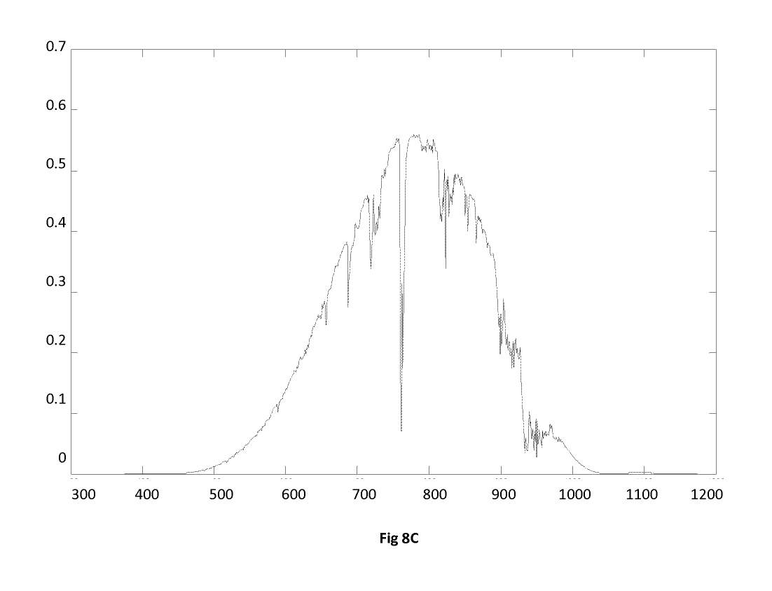

FIGS. 7A, 7B illustrate, in top and front views, respectively, an embodiment 700 configured to operate in a substantially vertical orientation while facing eastern/western directions. Accordingly, this embodiment employs a bi-facial PV cell and a vertical orientation of diffraction patterns of the gratings 720 of the embodiment 700. Due to the fact that illumination of the embodiment 700 is substantially symmetrical (see incident light 706, 708) with respect to a plane defined by the PV cells 710 (as compared between the illumination geometry in the morning and that in the afternoon), the same grating 720 operates to diffract light to different PV (as shown by arrows 730, 732 representing diffracted light) depending on the time of the day. An embodiment of the grating 720 is optimized to capture light incident within at least a right circular cone defined by an angular aperture of at least 46.9 degrees corresponding to the generatrix lines of such cone, as viewed along the −y-axis. In reference to FIGS. 7A and 7B, a diffraction grating pattern of each of the gratings in the array 720 (which, in the case of imprinted grating such as a blazed grating corresponds to the grating grooves or rulings, and in the case of a holographically-defined gratings corresponds to the iso-lines of refractive index distribution in a plane parallel to the plane of the grating) corresponds to the direction of the grating array, i.e. is substantially vertical in the local system of coordinates. FIGS. 8A, 8B, and 8C show dispersion characteristics of the grating 720 representing its diffraction efficiency; its angular dispersion; and the product of the diffraction efficiency, the atmospheric transmission curve and the response of the silicon, respectively.

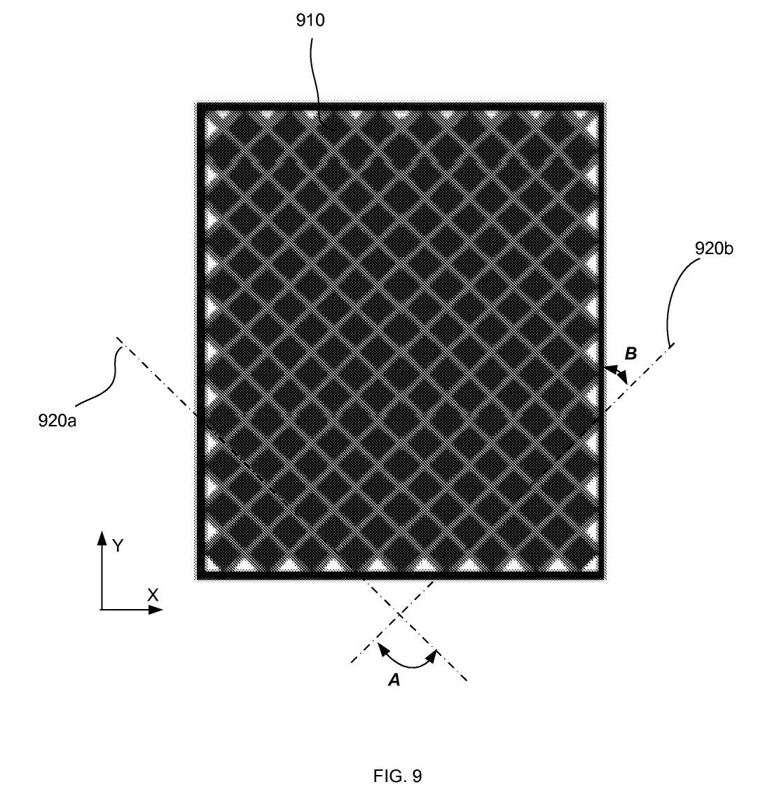

A related embodiment 900 of the invention, as shown in FIG. 9 in a front view, includes PV cells 910 and a diffractive element layer containing diffraction gratings 920a, 920b oriented such that their corresponding Bragg planes form a dihedral angle A. Generally, the value of A can vary, from embodiment to embodiment, within a range between 0 and 180 degrees. As shown in FIG. 9, A˜90 degrees and the grating pattern 920a, 920b is oriented, in the plane of the module (xy-plane), at about B=45 degrees to the x-axis. Such configuration of the gratings 920a, 920b is adapted to optimize the solar-energy collection by a module that faces a direction between the east/west and north/south (for example, the south-east).

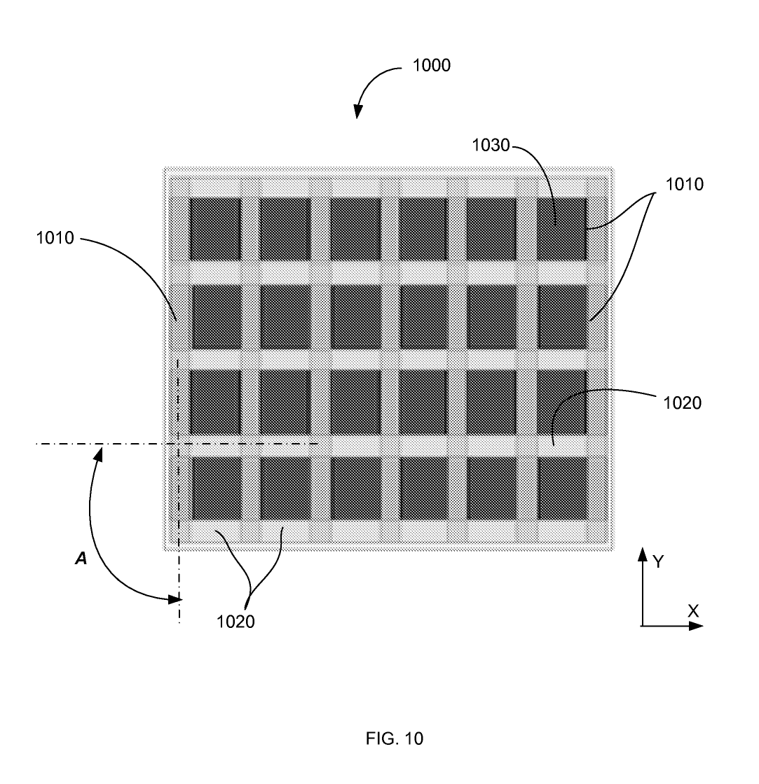

Another embodiment 1000, characterized by A˜90 degrees and B˜0 degrees, is shown in FIG. 10. Diffraction grating elements 1010 with vertically-oriented diffraction pattern optimize the performance of the module 1000 with respect to east-west orientation of the embodiment, while diffraction grating element 1020 with horizontally oriented pattern optimize the performance of the module 1000 with respect to north-south orientation. Accordingly, at least one of the (groups of) gratings 1010, 1020 receives sunlight and diffracts it towards the PV cells 1030 at any time during the day of any month of the year, regardless of at which angle with respect to the north-south/east-west coordinates the substantially-vertically positioned module 1000 is oriented.

It is worth mentioning that, in addition to optimizing the solar energy collection in any orientation with respect to the four cardinal directions (north, east, south, west), the vertically-mounted embodiments 900, 1000 of FIGS. 9 and 10 are conveniently configured to take advantage of reducing the cost of production of the employed PV cells 910, 1030. Indeed, when the diffraction gratings or diffraction grating arrays 920a, 920b and 1010, 1020 are configured to define substantially square grids, the elements of these grids are fitted with PV cells 910, 1030 that are also substantially square and, therefore, can be sliced off from the original ingots of Si (whether monocrystalline or polycrystalline) without additional re-shaping. Accordingly, the use of Si material per unit of area of the resulting embodiment of the PV module is reduced as compared to other implementations.

Embodiments of the present invention stem from the realization that an optical train formed by either a single diffraction grating and the PV cell of the HPC device or by spatially multiplexed diffraction gratings and the PV cell of the HPC device can be adapted to collect solar energy when the HPC device is positioned vertically (in local system of coordinates) and, moreover, be optimized for such collection for any orientation of a sunlight-collecting facet of the device with respect to the four cardinal directions. As discussed, in some specific embodiments, the optical train of an embodiment is adapted to include a layered stack of at least two substantially planar two-dimensional gratings one of which is carried by another. In this case, the upper grating (defined, for simplicity of illustration, as the one that is facing the sunlight incident at the module) diffracts a first portion of the incident light within the operational bandwidth of the upper grating to form a first beam of diffracted light that is further directed towards a sunlight-collecting surface of a PV cell of the system. The second portion of incident light (spectral components of which are substantially outside of the operational bandwidth of the upper grating) is transmitted by it towards the complementary so-called lower grating that is parallel to the upper grating and is reflected by that lower grating to form a second beam of diffracted light that is further directed towards a sunlight collecting surface of a PV cell of the system. At least one of the upper and lower diffraction gratings can be a grating holographically recorded in a material layer of the PV solar energy concentrator system of the invention. In a related embodiment, the optical train of the diffractive elements is defined by at least two diffraction gratings that are holographically recorded in the same volume of material such as to overlap in that volume. The layered structure of the system of the invention is configured to ensure that the directing of a diffracted beam of light produced by a grating of the embodiment towards a sunlight collecting surface of the PV cell is generally accomplished with the use of a total internal reflection at one of the surfaces of the solar energy concentrator system of the invention. Optical properties of a reflecting surface of the system are optionally enhanced with a reflecting thin-film layer deposited thereon.

It is appreciated that a specific nature and/or geometry of the employed diffractive elements does not change the scope of the invention. Accordingly, the examples of the embodiments are presented in reference to generalized “diffraction gratings” (such as, for example, linear or curvilinear diffraction gratings holographically recorded in a gelatin-based layer of the holographic optical film, HOF). Similarly, the spatial extent of either upper or lower diffraction grating employed in an embodiment of the invention does not change the principle of operation of the invention. While in the discussed examples it may be assumed that footprints of the upper and lower diffraction gratings of the stack (defined as extents of normal projections of these gratings on a plane of choice, for example, a plane defined by a PV cell) are substantially the same, the size of one of the gratings may generally differ from the size of another.

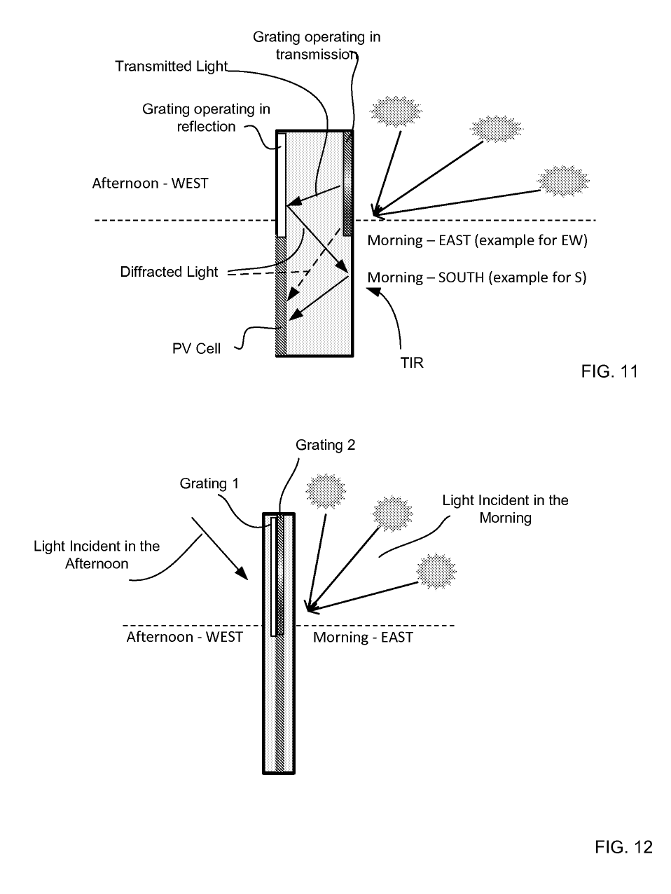

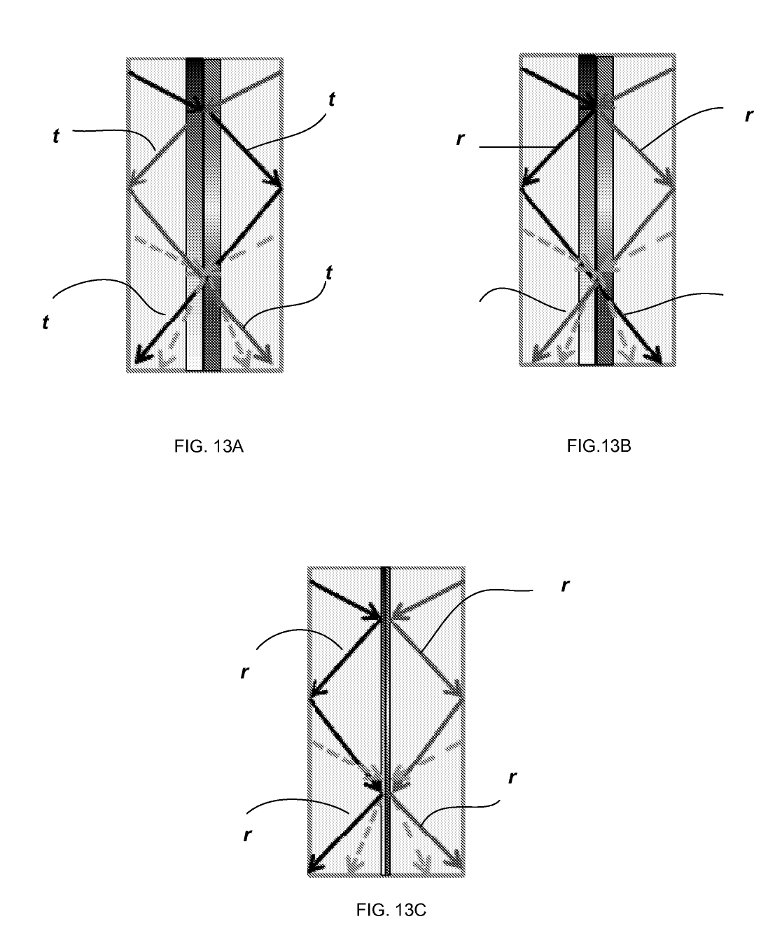

Accordingly, various modifications are envisioned within the scope of the invention. FIGS. 11 through 14 show schematics of some of such modified embodiments. FIG. 11, for example, illustrates the use of two gratings (one operating in transmission and one operating in reflection) that optionally have substantially equal and/or mutually overlapping normal projections on the plane defined by the light-collecting surface of the monofacial PV cell and that are spatially multiplexed to be separated by an encapsulating layer of the PV module of the invention. FIG. 12 shows the operation, throughout the day, of a HPC module employing a bifacial PV cell and a spatially multiplexed and adjoining first and second diffraction gratings (one operating in reflection and another operating in transmission) that are sandwiched to be substantially co-planar with the PV cell. FIGS. 13A, 13 B, and 13C show diagrams illustrating spatially-multiplexed stack of two holographically-defined gratings operating in transmission, two holographically-defined gratings operating in reflection, and two blazed gratings operating in reflection, respectively, for the use with an embodiment of a vertically-mounted HPC of the invention. Here, arrows marked with “t” represent transmitted light, arrows marked with “r” represent reflected light.

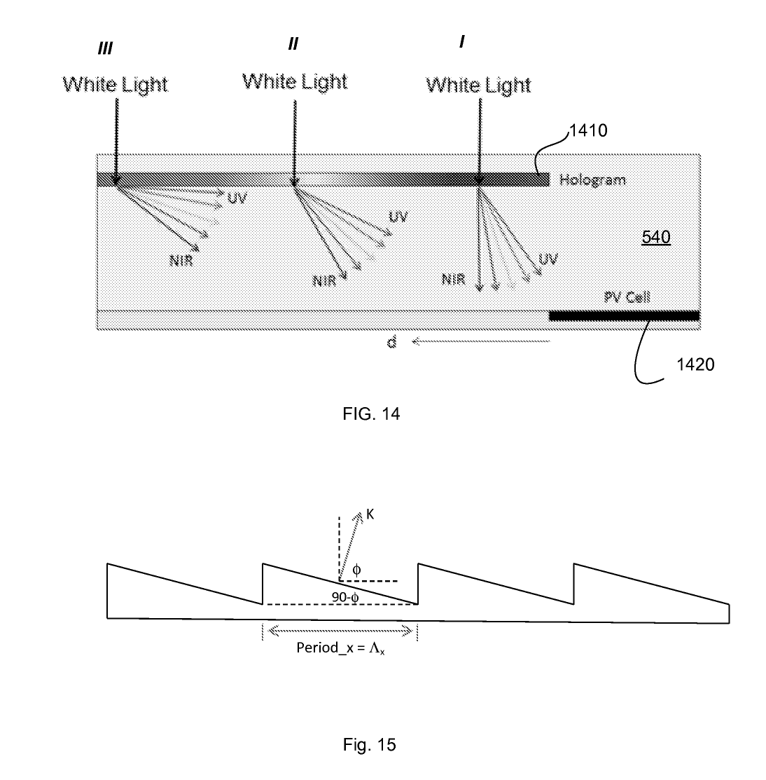

FIG. 14 illustrates an embodiment employing a spatially-nonuniform holographic grating 1410 characterized by at least one of the grating parameters (such as the period of the grating and/or the grating vector K and/or the angle φ at which the grating diffraction pattern is disposed with respect to a chosen direction, as known in the art) that is changing either incrementally or continually as a function of distance from the PV cell 1420. For example, as shown in FIG. 14, a non-uniform grating 1410 such a distribution of its diffractive parameter that ensures a continually-increasing angle of diffraction, for a chosen wavelength, with increasing distance from the PV cell 1420. For example, in one implementation, a grating period in region III of the grating 1410 is greater than a period in region II which, in turn, is greater than a period in region I. The grating vector K is expressed

\vec{K}=\vec{σ}−\vec{ρ}=k[(sin θ_{d}\hat{x}+cos θ_{d}\hat{z})−(sin θ_{Inc}\hat{x}+cos θ_{Inc}\hat{z})]

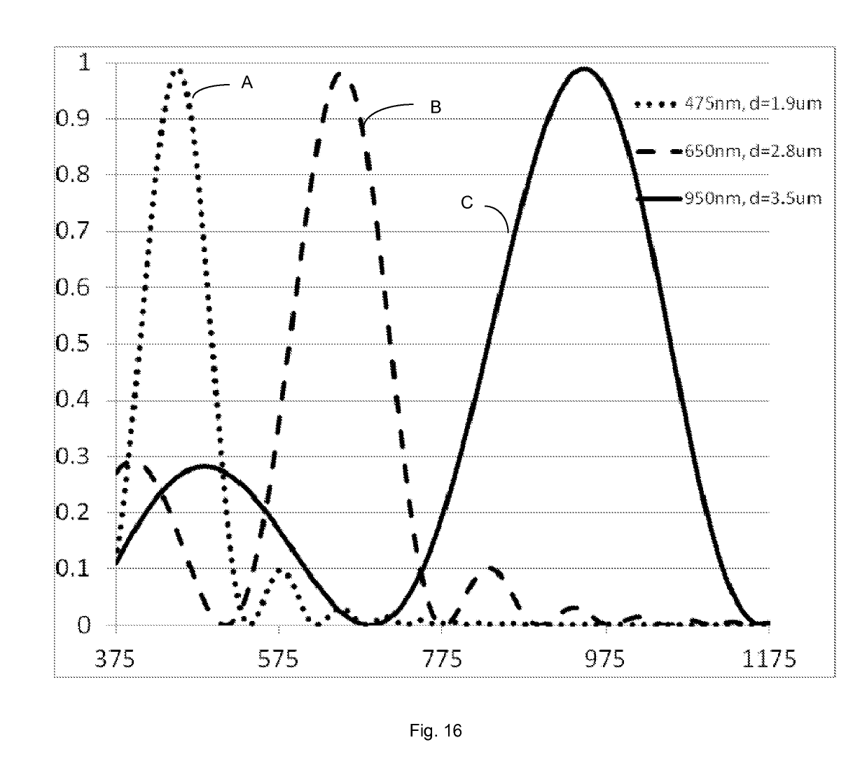

In an alternative embodiment (not shown), a stack of spatially-multiplexed gratings can be used. In configuring the parameters of the spatially-nonuniform grating such as the grating 1410 or those of a stack of gratings, care should be taken to avoid holographic recoupling between beams of light diffracted by different portions of the gratings. In particular, portions of the grating 1410 must be sufficiently dissimilar along its length for light diffracted in region III not to interact with light diffracted in either region II or region I as light passes through the diffractive optics stack. The stack is oriented so that each grating diffracts light in the desired direction for maximum efficiency. One possible stacking arrangement is to have the angle between the K vector of a given grating and a normal to the plane of the grating (referred to as a K-vector angle) in one of the regions be equal to but have the opposite sign as compared to those of the grating in another region. Geometry of the blazed grating is schematically illustrated in FIG. 15. An alternative stacking arrangement relates to FIG. 16, which illustrates curves representing spectral distributions of diffraction efficiency of three types of diffraction gratings (A, B, and C) characterized by different periods and, accordingly, by different wavelengths corresponding to optimal operation. In further reference to FIG. 14, in such an alternative solution, the gratings A, B, and C can be sequentially located in the regions I, II, and II of the diffraction element 1410. In another embodiment (not shown), the same three gratings can be stacked up on top of one another such as to define substantially equal orthogonal projections, on the plane of the PV cell, each of which is adjacent to or adjoins the PV cell.

The result of the changes should be checked in two ways. The diffracted angle/wavelength should be checked with the grating equation to make sure the grating is diffracting the light in the appropriate angles and wavelength. The region of maximum efficiency should be checked by matching the K-vector angle to the diffracted angle/wavelength.

A more rigorous analysis of the gratings can be conducted to fully optimize the periods as to maximize the total energy being delivered to the PV cell, either for instantaneous power, daily energy or yearly energy yields. For applications in which Total Internal reflection in a medium with a refractive index of n≈1.5 (glass-like or plastic-like materials is desired, θ_{diffraction}>42 degrees.

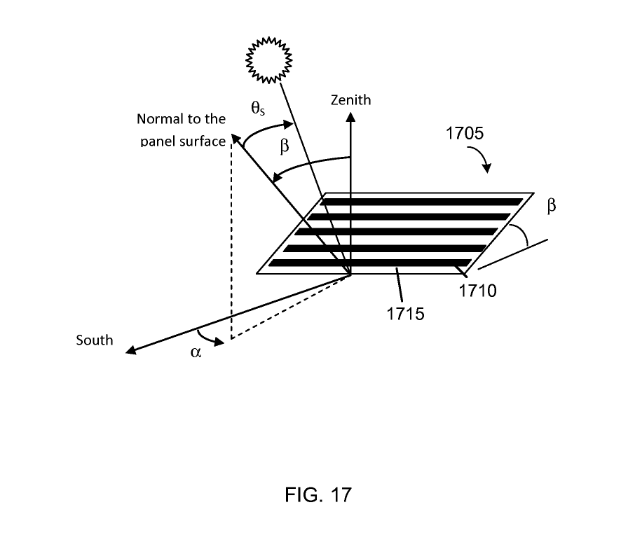

The idea of orienting HPC based PV modules at non-conventional angles may be generalized, and holograms may be designed that that useful levels of light concentration at non-conventional mounting angles other than vertical. FIG. 17 sets forth some of the geometrical parameters used in methods according to the invention to optimize concentrating hologram designs and mounting angles. In FIG. 17, a solar panel 1705 using holographic planar concentrators is shown. Solar panel 1705 includes an array of PV cells 1710 arranged in horizontal bands. Although the PV cells 1710 of FIG. 2 are pictured as being arranged in continuous horizontal bands, this is not a requirement, and in practice there may be small gaps between PV cells in a row for front to back electrical connections, bus wiring, and/or due to manufacturing tolerances. PV cells 1710 are encapsulated at least beneath an upper sheet of transparent material, and in certain cases, are sandwiched between an upper and lower sheet of transparent material. Exemplary transparent materials include glass, PMMA, acrylic, polycarbonate, COC or any other durable, optically transparent material. Above and below each row of PV cells, disposed in, on, or between the sheets of transparent material, are rows of holographic gratings 1715. For a given row of holographic gratings, an upper hologram diffracts light in an upper direction toward the adjacent, upper row of PV cells. The same row of holographic gratings includes a lower hologram that diffracts light in a lower direction toward the adjacent lower grating. For gratings that are disposed at the top or bottom of a panel (i.e., a first or last grating), these gratings are designed without upper and lower halves such that the entire grating diffracts in the direction of the adjacent PV cell.

The solar panel 1705 of FIG. 17 is designed in reference to solar geometry. Panel 1705 is mounted at a tilt angle β, which is the angle between the plane of the panel and the horizontal (i.e., a planar approximation of the surface of the earth below the panel.) Near noon on each day, the sun will reach a zenith, which is the maximum angular height above the horizon reached by the sun. The zenith angle is measured with respect to the vertical (e.g., a line normal to the surface of the Earth, which includes the Earth's center). As the sun moves through the sky during the course of the day, it traces out an azimuth angle α, which is defined in reference to south. In the northern hemisphere, where the sun traces out an arc across the southern sky, a solar panel will generally be oriented to the south. As is set forth above, conventionally, solar panels are mounted with a tilt angle that is equal to the latitude at which the panel is installed. This tends to place the panel such that its surface normal is parallel to the direction of incoming sunlight when the sun is near noon, which presents the maximum projected area of the panel to the sun, thereby maximizing the amount of light incident on the panel.

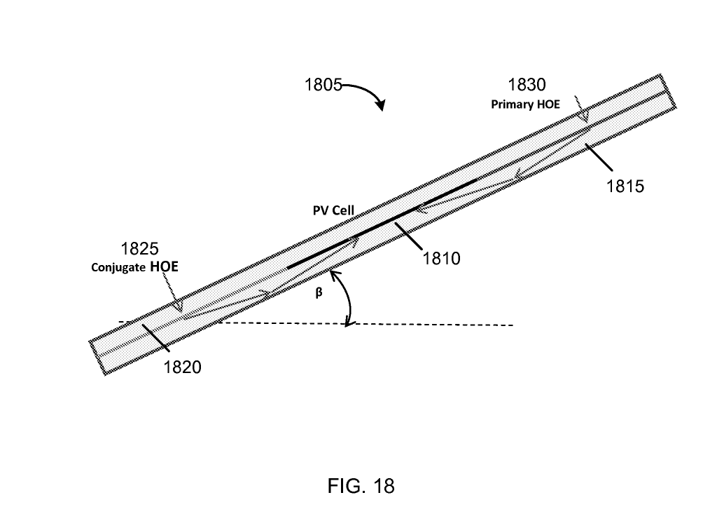

FIG. 18 shows a solar panel configuration using primary and conjugate holographic gratings according to the invention. The panel 1805 of FIG. 3 includes a photovoltaic chip 1810, which converts incident light within a specific wave band into electrical current. In the embodiment of FIG. 18, chip 1810 is a bifacial chip, but use of monofacial chips is acceptable if other parameters of the geometry of the panel of FIG. 18 are controlled to provide waveguiding to the front side of chip 1810. Chip 1810 is encapsulated between a first and second transparent panels 1815, 1820. In certain embodiments, panel material includes glass or optical transparent polymer material (e.g., PMMA, acrylic, polycarbonate, COC, etc.) and chip 1810 is encapsulated between first and second transparent panel with an optically transparent adhesive or epoxy (not shown). Together, transparent panels 1815, 1820 form a transparent material having a first and second surface, where the surfaces are mutually parallel. The panel of FIG. 18 includes a primary holographic optical element 1830 located co-planar with and above chip 1810, and a conjugate holographic optical element 1825 located co-planar with and below chip 1810. Each HOE acts as a biased or blazed diffraction grating and is designed to preferentially diffract normal incidence light into a single diffractional order oriented in the direction of chip 1810. In certain embodiments, holograms 1830, 1825 are bulk or phase holograms recorded in dichromated gelatin. In operation, light incident on panel 1805 is diffracted by primary hologram 1830 down and toward chip 1810 and is diffracted by conjugate hologram 1825 up and toward chip 1810. Light diffracted by each of the HOEs is guided by total internal reflection to back side of PV chip 1810. In certain embodiments of the invention, the designs for primary hologram 1830 and conjugate hologram 1825 will be dissimilar, not only in that they are designed to diffract light in opposite directions, but also, they designed to diffract light to different degrees.

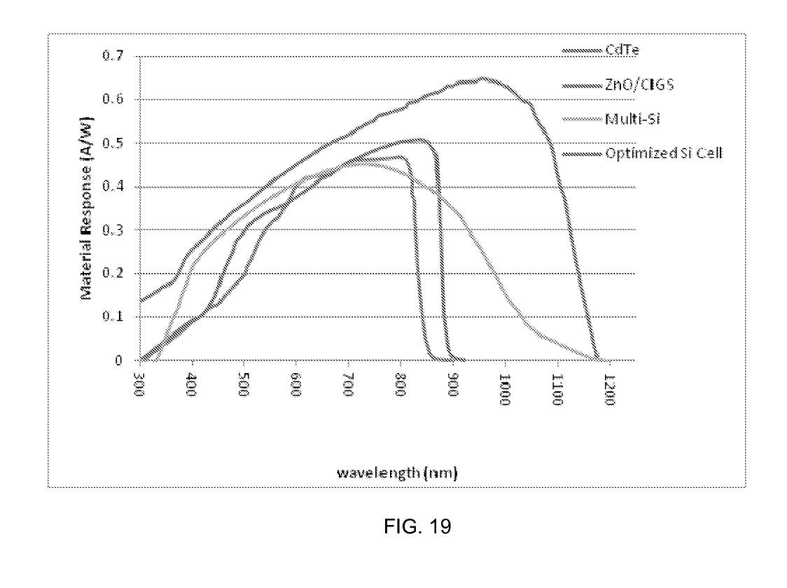

In one embodiment, the invention comprises a method of characterizing the performance and optimizing the design of primary and conjugate holograms to concentrate light onto an adjacent PV chip. In a method according to an embodiment of the invention, holographic performance is determined by using custom code developed by Applicant, which models holographic performance by approximate couple wave analysis (ACWA). The ACWA custom code was written for MatLab, and is attached hereto as an Appendix. The ACWA code simulates hologram interactions with the photovoltaic material response for the photovoltaic material being modeled (i.e., where the material being modeled has the spectral response shown in FIG. 19) for the full seasonal sun angle movement and spectrum, simulating the sun position every 15 days and throughout the day. An acceptable daily angular design range for solar concentrators covers ⅔ of the daily sun angle centered around noon, defined as 8 hours of an 12 hour day or ⅔ of the day. The ACWA code simulates the angular range for 70% of each day, subdividing the portion of the day under analysis into 17 daily points centered on the noon sun position, then varying the angle itself depending on the date. Care is taken in the simulation to weight the energy collection values by the day length to accurately integrate energy for the year. Fresnel reflections, cosine area fall-off and atmospheric absorption effects are also accounted for in the simulations. The temporal parameters set forth in the exemplary ACWA code should not be construed as limiting, as any other level of granularity is acceptable. For example, it is acceptable to expand the solar arc modeled (i.e., for the entire day, sunrise to sunset), to sample more frequently throughout the day (i.e., every 5 minutes, rather than every 45 minutes), and/or to simulate the sun position (i.e., its seasonal position above the horizon) every day, rather than every 15 days.

The ACWA code developed serves primarily as a hologram design tool and secondarily as an estimator of the yearly effective energy concentration by the holograms (Joules_hologram/Joules_PV). The effective energy concentration for the previously defined design space (70% of the day) is calculated, not the total integrated energy for a full day. Because of the cosine fall off (i.e., the reduced projected area of a PV chip presented to the sun as the sun's angle changes), and secondarily due to the Fresnel reflection losses in the glass/air interface (which increase as the angle between the surface normal of the cell and the sun increases) and the atmospheric absorption at greater incidence angle, most of the energy collected by a non-tracking PV panel occurs during ⅓ of the day centered around noon.

With the ACWA tool in place to model hologram performance, the invention allows for concentrating HOEs to be optimized for a given installation latitude. This is done by characterizing the performance of model holograms using the ACWA code while varying the construction parameters that define the hologram through the following equations:

$${K}^{->} = {σ}^{->} - {ρ}^{->} = k [ ( sin {θ}_{d} \hat{x} + cos {θ}_{d} \hat{z} ) - ( sin {θ}_{Inc} \hat{x} + cos {θ}_{Inc} \hat{z} ) ] ;$$

$$Slant \text{:} ∅ = {tan}^{- 1} \frac{{K}_{x}}{{K}_{z}}$$

$$Λ = \frac{2 π}{\vert {K}^{->} \vert}$$

$${Λ}_{x} = \frac{Λ}{sin ∅}$$

$${Λ}_{x} [ ( sin {θ}_{d} - sin {θ}_{Inc} ) ] = m \frac{λ}{{n}_{o}}$$

φ is the slant angle of the grating, d is the hologram thickness, Λ is the fringe period and \vec{K} is the grating vector that is perpendicular to the plane defined by the grating fringes. In the grating equation, Λₓ is the grating spacing in the x dimension, i.e., in the plane of FIG. 3 and parallel to the plane containing the PV chip and the primary and secondary hologram, and nₒ is the index of the material in which the holographic grating is immersed (e.g., 1.49). For a given hologram simulation, the construction angle 1 (θᵣ)=θinc and the construction wavelength (λ) is varied while keeping the construction angle 2 fixed (θ₂)=θ_{d}, thus defining a hologram structure (by determining Λₓ), the performance of which is then simulated in the ACWA code. Construction angle 2 (θ₂) is fixed at an output angle necessary to cause diffracted light to undergo total internal reflection within the panel in which the holographic grating is immersed, so that the light is wave guided to the PV chip. For one modeling/optimization methodology (θ₂) is fixed at 50 degrees. The performance of each hologram is simulated as the input construction angle and the design wavelength are varied, using the ACWA code, throughout the day/year for the given latitude/mounting angle and compared to an equal area of PV material to get the effective concentration.

Certain assumptions may be made as part of the ACWA simulation. Since holograms according to the invention are bulk or phase holograms, they do not have infinitesimal thickness. Accordingly, the index modulation and effective thickness of the hologram design being modeled are assumed. In one embodiment, the index modulation was fixed at 0.072. In other embodiments, the index modulation was fixed at 0.099. Both of these values are achievable with holographic gratings recorded by Applicants in dichromated gelatin. Additionally, in certain embodiments, the thickness of the holographic lawyer is assumed to be 2.15 um. The figure of merit arrived at through the ACWA code is concentration. For a given hologram, at a given latitude, at a given tilt angle, with a given PV chip material, and with a given geometry, with a yearly performance modeled in the ACWA code, concentration is the amount of power the hologram adds to the adjacent PV material per unit of area. Thus, for holograms modeled for concentration to a single crystal Si PV chip, the concentration figure represents the added power contributed by the hologram as a percentage of the power that would result from an equal area of active PV material.

The methodology of the instant invention was used to determine the optimum design parameters for primary and conjugate holograms for a solar panel with a latitude tilt angle, that is, a panel where the tilt angle is equal to the latitude of its installation location. A 36 degree installation latitude and tilt angle were selected because 36 degrees is a good average for the solar feasible areas of the United States. In addition to the assumptions set forth above, certain geometrical assumptions regarding the panel configuration were made for find the optimum designs for the 36 degree latitude case. To optimize holograms for a latitude condition, the holograms were assumed to be are arranged on either side, top and bottom, of the photovoltaic cell in the same plane, as in FIG. 18. The PV material width was fixed at 25 mm and the panel thickness was fixed at 9.5 mm. For these conditions the hologram half width is >17.1 mm to avoid any recoupling (i.e., light diffracted by the hologram intercepting the hologram and being coupled out of the panel after one TIR bounce). To maintain a 1:1 hologram to cell ratio, the hologram half width with was set to 12.5 mm.

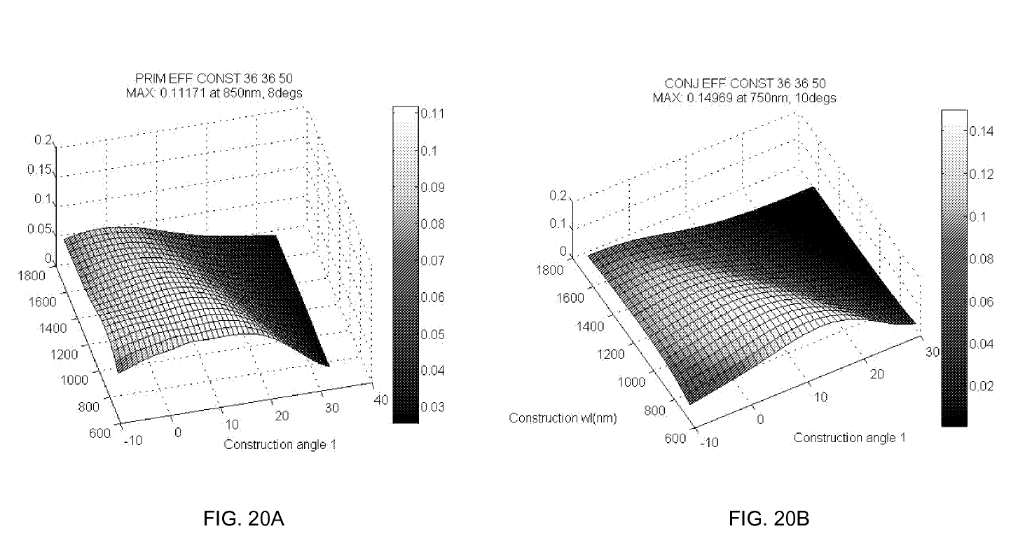

FIG. 20A and FIG. 20B show the results of the application of the hologram characterization and optimization methodology set forth above as applied to a theoretical single-crystal silicon PV chip installed at 36 degrees latitude with a tilt angle equal to latitude. It can be seen by the results of FIGS. 20A and 20b that varying the hologram construction parameters set forth above (the input ray construction angle and the design wavelength) that a design configuration for maximum concentration can be achieved for both these parameters. For the installation conditions of FIGS. 20a and 20b (i.e., a tilt angle of 36 degrees, oriented southwardly, for an installation position at 36 degrees latitude, with a single-crystal silicon PV chip, a 50 degree output construction angle, and the geometry of FIG. 18) a maximum solar concentration of about 0.112 can be achieved for a primary hologram having an input construction angle of 8 degrees and a design wavelength of 850 nm. A conjugate hologram can achieve a maximum solar concentration of 0.150, with an input construction angle of 10 degrees and a design wavelength of 750 nm. It will be observed from FIGS. 20A and 20b that for latitude mounts (that is, where the tilt angle is equal to latitude), and where the holograms are used above and below the PV chip in the same plane (in the geometry of FIG. 18), that optimal concentration occurs where the conjugate hologram and the primary hologram have different design parameters.

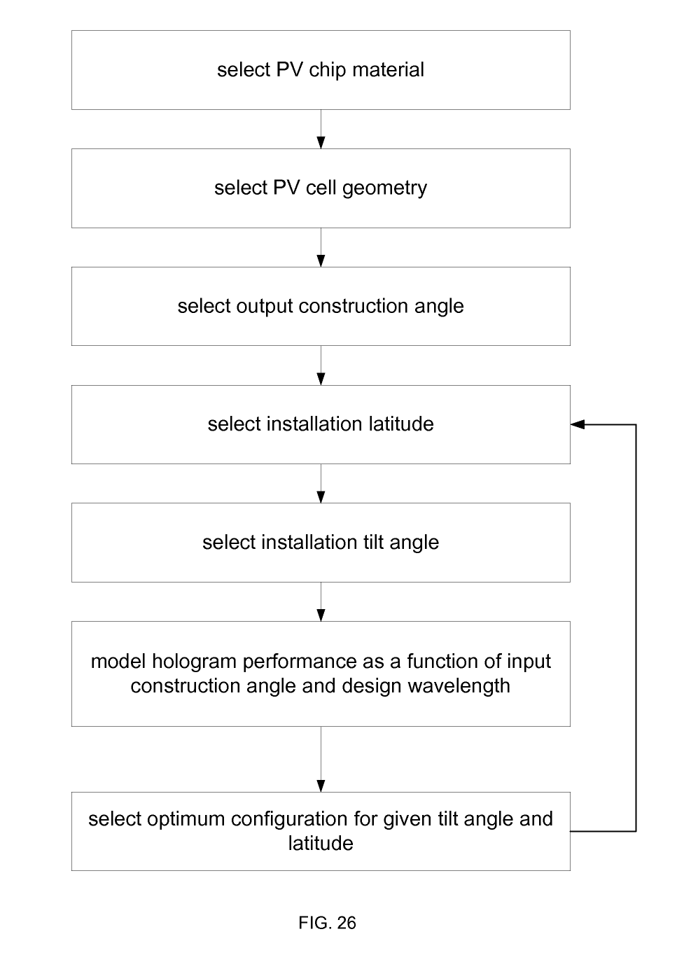

The method used above to optimize primary and conjugate hologram designs for a latitude mounting condition are generalized, in certain embodiments of the invention, to select optimum hologram configurations for non-latitude conditions. The general methodology includes the steps of selecting a PV chip material and a set of assumptions about the geometry of the solar cell (e.g., that it has the geometry set forth above in FIG. 18), selecting an installation latitude, selecting an installation tilt angle, and selecting an output construction angle under the grating equation (i.e., a construction angle that results in TIR under the chosen geometry). Hologram performance is then modeled as a function of input construction angle and design wavelength, where these parameters are defined according to the grating equation. For each hologram configuration selected (i.e., for each grating spacing determined for a given input construction angle, output construction angle and design wavelength), the performance of the modeled design is evaluated by calculating the concentration resulting from that design. In certain embodiments, this evaluation is done using ACWA theory to determine the response of the PV chip over a predetermined portion of every day over a predetermined portion of a year. Exemplary modeling parameters include modeling performance over 70% of each day (centered about noon) for every day of the year. The hologram design that yields the maximum concentration is selected. These steps are optionally repeated for other design latitudes, tilt angles, PV materials, etc. The steps of an exemplary method of hologram design are set forth in FIG. 26.

When the design and optimization methodology set forth above is applied for different PV materials and mounting conditions, hologram designs that yield far higher levels of concentration (as compared to latitude) can be obtained for specific mounting conditions. For the non-latitude mounting case, the methodology of the invention was applied under slightly different geometrical assumptions. As in the latitude mounted case, the holograms modeled and optimized for non-latitude mounting were arranged on top or under the photovoltaic cell, in the same plane. The PV material width was fixed at 17.1 mm and the panel thickness was fixed at 9.5 mm. For these conditions the hologram was >17.1 mm to avoid any recoupling. To maintain a 1:1 hologram to cell ratio, the hologram width was set to 17.1 mm.

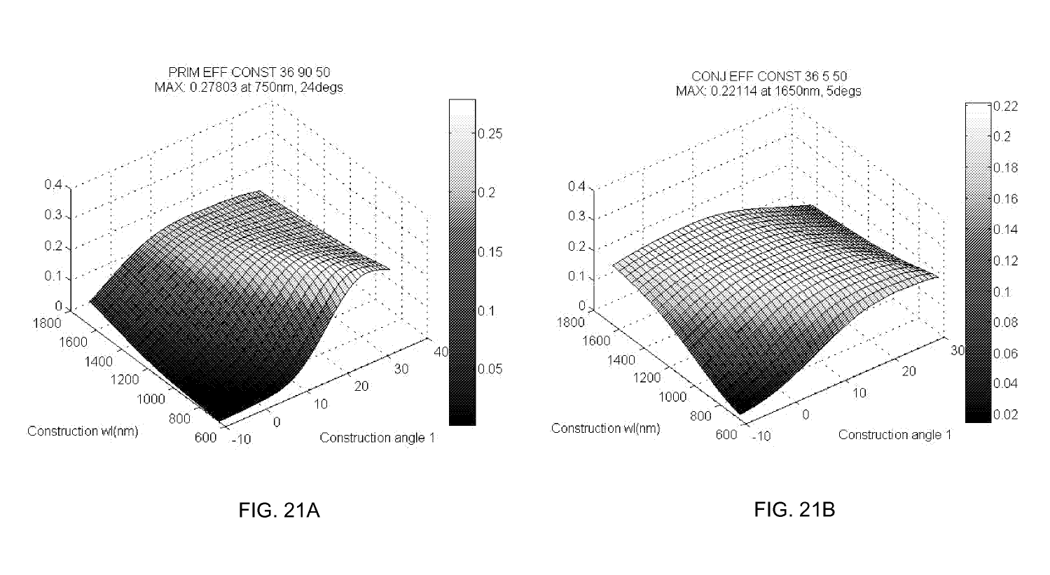

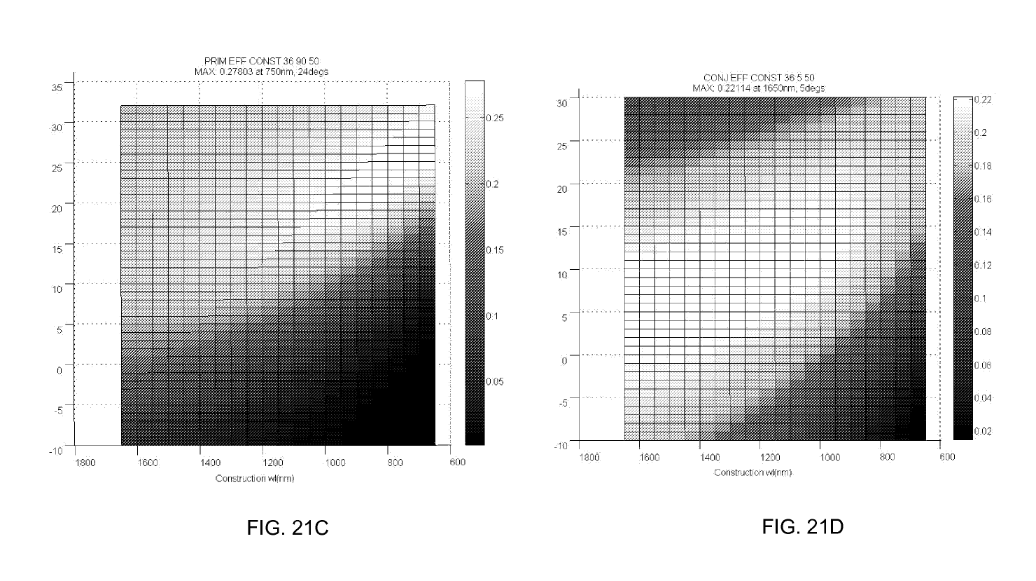

FIG. 21A is a chart showing the solar concentration achievable by a primary hologram for a vertical mounting condition as a function of construction angle and design wavelength used with a single-crystal silicon PV chip located at 36 degrees north latitude. A vertical mounting position means that the tilt angle β shown in reference to FIG. 3 is at or near 90 degrees. This mounting condition might occur when a solar panel is mounted on the south-facing facade of a tall office building (according to the methodologies set forth above). It should be noted that by encapsulating the PV chip in a wave guiding structure, such as the structure provided by transparent panels 315, 320 in FIG. 18, a primary hologram located on an upper adjacent side from a PV chip has to provide less deviation to diffract incoming light such that it can propagate down the waveguide to the PV cell via TIR. In other words, the geometry of a vertical mounting condition provides assistance to the primary hologram, which has to do less work as a result. This means that the fall-off of diffraction efficiency for wavelengths for which the hologram is not optimized is less of a concern for a primary hologram under a vertical mounting condition. A trade off is that a conjugate, or lower, hologram in a vertical mounting configuration can provide comparatively little concentration, the diffraction angle being too great to achieve with much efficiency. When a panel according to the invention is fabricated in the manner of FIG. 17, with alternating horizontal bands of holograms and PV chips, the entire band of holograms above a given strip of PV cells can be a primary hologram designed in the manner of the hologram of FIG. 21A. In other words, for a vertical mounting situation, there need not be a conjugate hologram to diffract light up toward a PV chip. Instead, another primary hologram can be placed below a given PV chip, which diffracts light down toward the next PV chip.

As can be seen in FIG. 21A, assuming a vertically mounted panel, located at 36 degrees latitude, with a single crystal silicon PV chip, and a 50 degree output construction angle, a maximum concentration of 0.278 occurs at an input construction angle of 24 degrees and a design wavelength of 750 nm. Even with the contribution of a conjugate hologram ignored, with a concentration of 0.278 from a primary hologram, a vertically mounted PV panel with a properly designed holographic concentrator can achieve more than twice the concentration of a latitude mounted panel that uses both primary and conjugate holograms.

Many other design configurations achieve similar concentrations. FIG. 21C is the chart of FIG. 21A for a vertically mounted primary hologram flattened to show an advantageous range of design conditions for achieving high concentration. As can be seen from FIG. 21C, there is a region of design conditions that can be used to achieve concentrations above 0.25. For example, holograms with a design wavelength around 900 nm and a construction angle of between 19 and 24 degrees would fall within this region and yield high levels of concentration. As can be seen from FIG. 21C, other configurations are possible and advantageous as well.

FIG. 21B is a chart showing the solar concentration achievable by a conjugate (i.e., lower) hologram for a near-horizontal mounting condition as a function of construction angle and design wavelength used with a single-crystal silicon PV chip located at 36 degrees north latitude. The tilt angle of the panel modeled in FIG. 21B is 5 degrees. As can be seen by FIG. 21B, assuming a 5 degree mounted panel, located at 36 degrees latitude, with a single crystal silicon PV chip, and a 50 degree output construction angle, a maximum concentration of 0.22 occurs at an input construction angle of 5 degrees and a design wavelength of 1650 nm. As in the vertical case of FIG. 21A, a primary (upper) hologram is not efficient under a horizontal mounting condition, but the upper space can be used for another conjugate hologram diffracting light to yet another PV chip located above the hologram on the panel.

Many other design configurations achieve similar levels of concentration. FIG. 21D is the chart of FIG. 21B for a near-horizontal mounted conjugate hologram flattened to show an advantageous range of design conditions for achieving high concentration. As can be seen from FIG. 21D, there is a region of design conditions that can be used to achieve concentrations above 0.21. For example, holograms with a design wavelength around 1300 nm and a construction angle of between 5 and 11 degrees would fall within this region and yield high levels of concentration. As can be seen from FIG. 21D, other configurations are possible and advantageous as well.

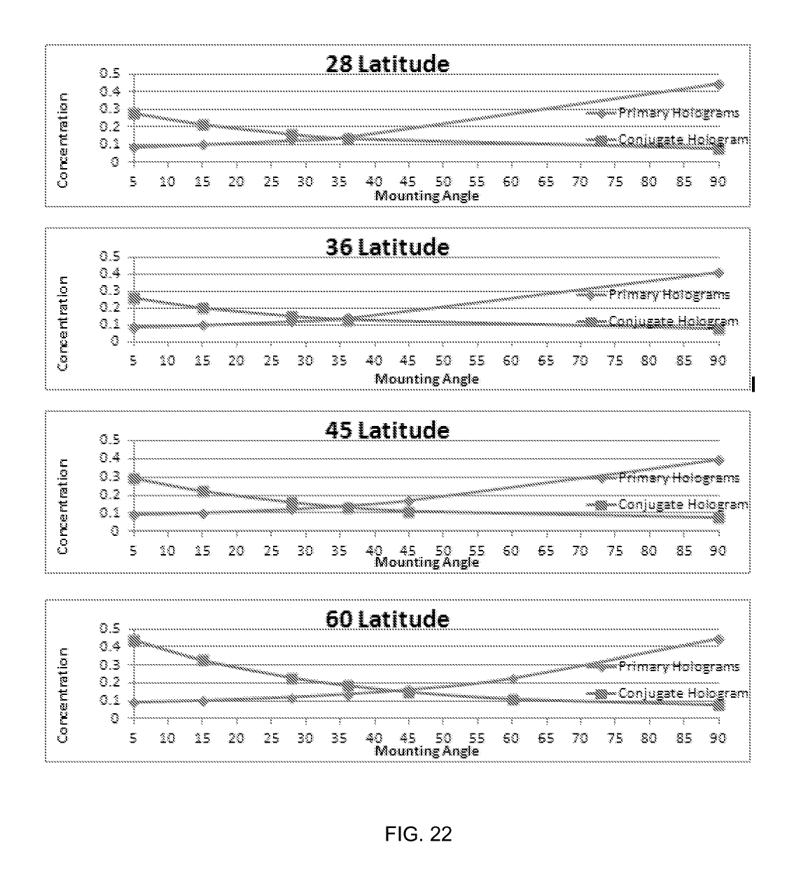

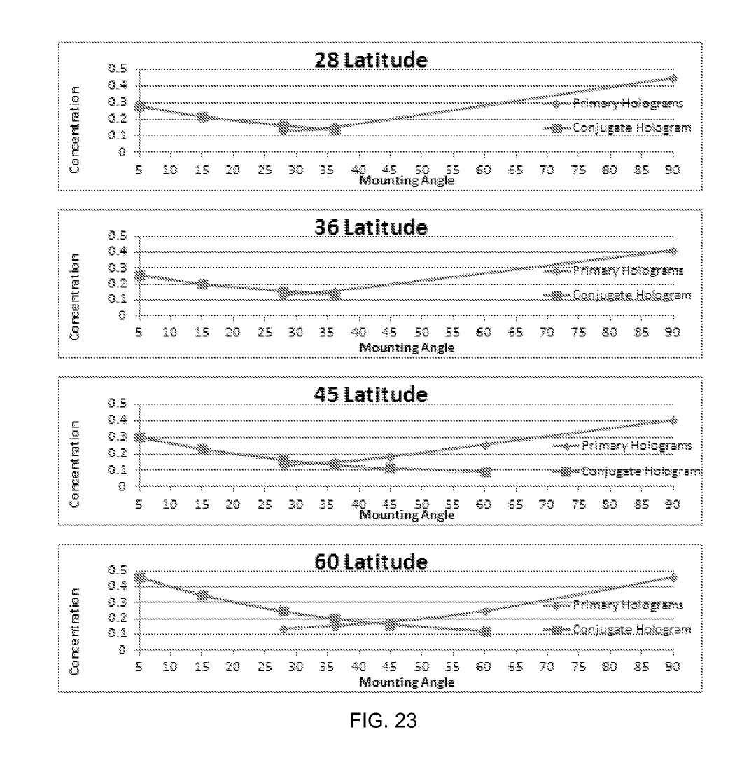

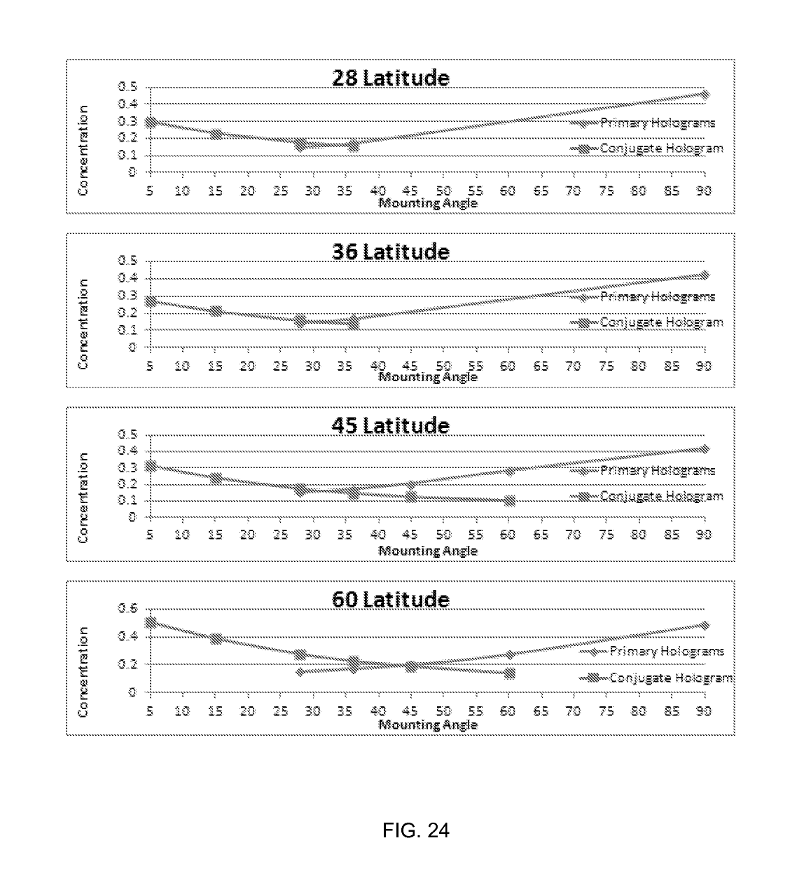

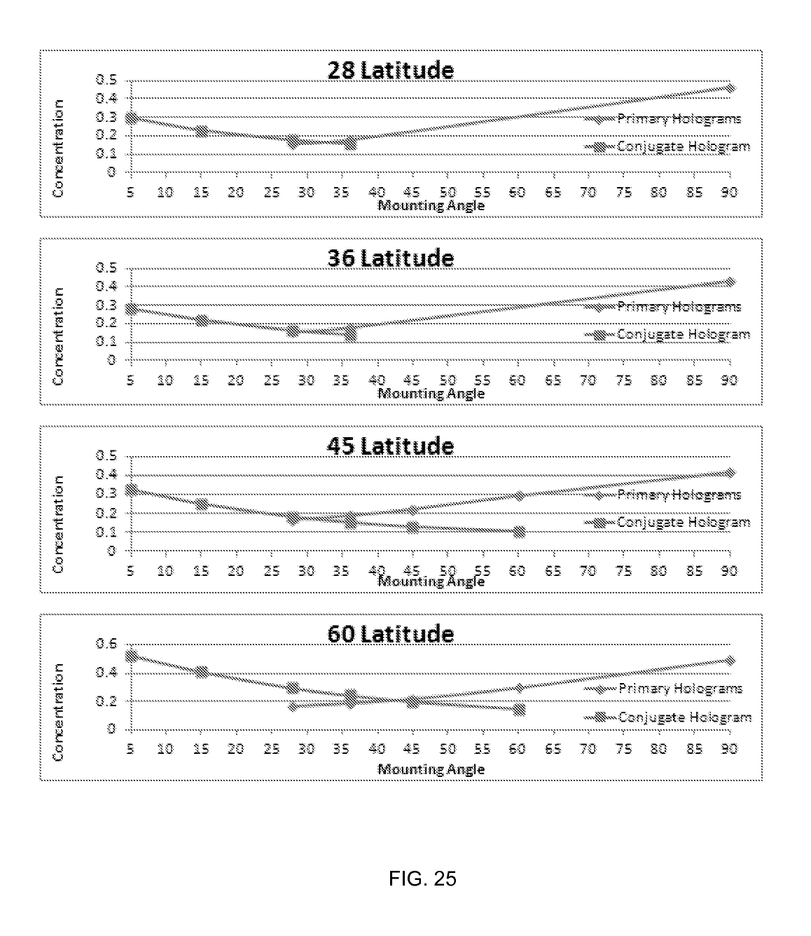

The basic methodology can be iterated to find the maximum achievable concentrations for primary and secondary holograms for all latitudes and mounting angles. FIGS. 22-25 show the maximum achievable concentrations for primary and conjugate holograms at various latitudes as a function of mounting angle for single crystal silicon (FIG. 22), poly silicon (FIG. 23), CIGS (FIG. 24) and CdTe (FIG. 25) photovoltaic chips.

The invention should not be viewed as being limited to the disclosed embodiments. Envisioned claims may be directed to at least a system and/or method for fabrication of a holographic optical film preform, an article of manufacture produced with the use of such system and/or method, and a computer program product for use with a system and/or method of an embodiment of the invention. Indeed, while the preferred embodiments of the present invention have been illustrated in detail, it should be apparent that other modifications and adaptations to those embodiments might occur to one skilled in the art without departing from the scope of the present invention.

### APPENDIX

The source code comprising the Appendix embodies one of Applicant's methods for determining the ideal performance of a concentrating hologram. The ACWA code simulates hologram interactions with the photovoltaic material response and the full seasonal sun angle movement and spectrum. The ACWA code is written for MatLab.

1. A solar energy concentrator having a front configured to be exposed to sunlight and comprising
a photovoltaic (PV) module layer including a PV cell that defines a PV plane corresponding to the front;
a first diffraction grating disposed in a first plane that is substantially parallel to the PV plane, the first diffraction grating having a first diffraction pattern defining a first direction; and
a second diffraction disposed in a second plane that is substantially parallel to the PV plane, the second diffraction grating having a second diffraction pattern defining a second direction, the first and second directions forming an angle;
wherein said concentrator is configured to have light diffracted by at least one of the first and second diffraction gratings to be totally internally reflected towards the PV cell at a surface of the concentrator.

2. A solar energy concentrator according to claim 1, wherein the first diffraction grating is configured such that sunlight that has interacted with the second diffraction grating interacts with the first diffraction grating.

3. A solar energy concentrator according to claim 1, wherein said PV cell includes a plurality of PV cells, wherein the first diffraction grating includes a first array of gratings having substantially equal spatial orientation and the second diffraction grating includes a second array of gratings having substantially equal spatial orientation, said first and second arrays defining areas bounded by gratings from said arrays, and PV cells from said plurality of PV cells disposed in said areas.

4. A solar energy concentrator according to claim 1, wherein the first and second diffraction gratings include holographic diffraction gratings.

5. A solar energy concentrator according to claim 1, wherein the first and second diffraction gratings have substantially co-extensive normal projections on the plane defined by the PV cell.

6. A solar energy concentrator according to claim 1, wherein the first and second diffraction gratings are adjoining one another.

7. A solar energy concentrator according to claim 1, further comprising an optical layer encapsulating at least one of said PV cell and first and second diffraction gratings.

8. A solar energy concentrator according to claim 1, wherein the PV cell includes a monofacial PV cell.

9. A solar energy concentrator according to claim 1, further comprising first and second optically-transparent substrates sandwiching said photovoltaic module layer, said first diffraction grating, and said second diffraction grating therebetween to define an optical stack, said second substrate corresponding to the front, said optical stack configured to ensure that light that has interacted with the second diffraction grating is totally internally reflected by a surface of the optical stack towards the PV cell, and that light that has interacted with the first diffraction grating is totally internally reflected by a surface of the optical stack towards the PV cell.

10. A solar energy concentrator according to claim 9, wherein the PV cell includes a bifacial PV cell and the optical stack is configured to have the light, which has interacted with the first diffraction grating, to be received by a face of the PV cell that is opposite to the front.

11. A solar energy concentrator according to claim 1, wherein at least one of the first and second diffraction gratings has a parameter that varies as a function of a distance between a point at which such parameter is defined and the PV cell.

12. A method of designing a hologram for concentrating solar energy onto a photovoltaic chip, the hologram being characterized by a first construction angle, a second construction angle and a design wavelength, the method comprising:
selecting a photovoltaic chip material;
selecting a photovoltaic cell geometry;
selecting a first construction angle;
selecting an installation latitude;
selecting an installation tilt angle;
modeling hologram performance as a function of a second construction angle and a design wavelength; and
selecting a combination of second construction angle and design wavelength that yields the optimum performance for a given tilt angle and latitude.

13. The method of claim 12, wherein the step of modeling hologram performance as a function of a second construction angle and a design wavelength comprises using approximate couple wave analysis to determine the amount of light concentrated by a hologram onto an adjacent photovoltaic chip throughout the year.

14. The method of claim 12, wherein the first construction angle is selected to be above the critical angle for a panel material in which the hologram of claim 12 is to be embedded.

15. A photovoltaic panel comprising:
a photovoltaic chip embedded in a transparent material, the transparent material having a first surface and a second surface, the surfaces being mutually parallel, the photovoltaic chip having a spectral response such that the photovoltaic chip is capable of converting incident light within a predetermined wavelength range into electrical current;
a primary hologram located above and adjacent to the photovoltaic chip and embedded in the transparent material such that it is substantially coplanar with said photovoltaic chip, the primary hologram being characterized by a first construction angle, a second construction angle and a design wavelength;
wherein the primary hologram and the photovoltaic chip are substantially parallel to the first and second surfaces;
wherein the primary hologram acts as a diffraction grating, diffracting light within said predetermined wavelength range that is incident on the first surface of the transparent material at a first angle laterally at a second angle in a downward direction toward the photovoltaic chip; and
wherein the second angle is such that light diffracted by the primary hologram undergoes total internal reflection upon intersection with the second surface.

16. The photovoltaic panel of claim 15, wherein the panel has a tilt angle that is substantially equal to the latitude of the location of the panel's installation, wherein tilt angle is the angle made between the plane of the photovoltaic chip and the local horizontal.

17. The photovoltaic panel of claim 15, wherein the panel has a tilt angle that is not equal to the latitude of the location of the panel's installation, wherein tilt angle is the angle made between the plane of the photovoltaic chip and the local horizontal.

18. The photovoltaic panel of claim 17, wherein the tilt angle is substantially 90 degrees.

19. The photovoltaic panel of claim 15, wherein the primary hologram can be characterized according to a first construction angle, a second construction angle, and a design wavelength, and wherein the first construction angle is chosen to be above the critical angle of the transparent material, and the second construction angle and design wavelength are chosen to yield a concentration of greater than 0.25.

20. The photovoltaic panel of claim 15, further including a conjugate hologram located below and adjacent to the photovoltaic chip and embedded in the transparent material such that it is substantially coplanar with said photovoltaic chip, the conjugate hologram being characterized by a first construction angle, a second construction angle and a design wavelength;
wherein the conjugate hologram and the photovoltaic chip are substantially parallel to the first and second surfaces;
wherein the conjugate hologram acts as a diffraction grating diffracting light within said predetermined wavelength range that is incident on the first surface of the transparent material at a first angle laterally at a third angle in an upward direction toward the photovoltaic chip; and
wherein the third angle is such that light diffracted by the conjugate hologram undergoes total internal reflection upon intersection with the second surface.
